(19) United States
(12) Patent Application Publication
(10) Pub. No.: US 2024/0079277 A1
(43) Pub. Date: Mar. 7, 2024

(54) SEMICONDUCTOR DEVICE STRUCTURE WITH GATE STACK AND METHOD FOR FORMING THE SAME

(71) Applicant: Taiwan Semiconductor Manufacturing Company, Ltd., Hsinchu (TW)

(72) Inventors: Wang-Chun HUANG, Kaohsiung City (TW); Pei-Yu WANG, Hsinchu City (TW)

(73) Assignee: Taiwan Semiconductor Manufacturing Company, Ltd., Hsinchu (TW)

(21) Appl. No.: 18/152,651

(22) Filed: Jan. 10, 2023

Related U.S. Application Data
(60) Provisional application No. 63/404,315, filed on Sep. 7, 2022.

(51) Int. Cl. H01L 21/8238; H01L 21/28; H01L 23/535; H01L 27/092; H01L 29/06; H01L 29/423; H01L 29/49; H01L 29/66; H01L 29/775

(52) U.S. Cl. CPC H01L 21/823842; H01L 21/28088; H01L 21/823807; H01L 21/823871; H01L 21/823878; H01L 23/535; H01L 27/092; H01L 29/0673; H01L 29/42392; H01L 29/4908; H01L 29/66439; H01L 29/775

(57) ABSTRACT

A method for forming a semiconductor device structure is provided. The method includes providing a substrate, an isolation layer, a gate stack structure, and a dielectric layer. The method includes partially removing the gate stack structure to form a first trench in the gate stack structure. The method includes forming an isolation structure in the first trench. The method includes removing the first gate stack and the second gate stack to form a first recess and a second recess in the dielectric layer. The method includes forming an n-type gate stack and a p-type gate stack in the first recess and the second recess respectively. The method includes forming a conductive line over the n-type gate stack, the p-type gate stack, and the isolation structure. The conductive line electrically connects the n-type gate stack to the p-type gate stack.

### PRIORITY CLAIM AND CROSS-REFERENCE

This application claims the benefit of U.S. Provisional Application No. 63/404,315, filed on Sep. 7, 2022, and entitled “SEMICONDUCTOR DEVICE STRUCTURE WITH GATE STACK AND METHOD FOR FORMING THE SAME”, the entirety of which is incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1Q are cross-sectional views of various stages of a process for forming a semiconductor device structure, in accordance with some embodiments.

FIG. 1A-1 is a perspective view of the semiconductor device structure of FIG. 1A, in accordance with some embodiments.

FIG. 1A-2 is a cross-sectional view illustrating the semiconductor device structure along a sectional line II-II′ in FIG. 1A-1, in accordance with some embodiments.

FIG. 1A-3 is a cross-sectional view illustrating the semiconductor device structure along a sectional line III-III′ in FIG. 1A-1, in accordance with some embodiments.

FIG. 1A-4 is a top view of the semiconductor device structure of FIG. 1A, in accordance with some embodiments.

FIG. 1B-1 is a top view of the semiconductor device structure of FIG. 1B, in accordance with some embodiments.

FIG. 1C-1 is a top view of the semiconductor device structure of FIG. 1C, in accordance with some embodiments.

FIG. 1F-1 is a top view of the semiconductor device structure of FIG. 1F, in accordance with some embodiments.

FIG. 1P-1 is a top view of the semiconductor device structure of FIG. 1P, in accordance with some embodiments.

FIG. 1P-2 is a cross-sectional view illustrating the semiconductor device structure along a sectional line II-II′ in FIG. 1P-1, in accordance with some embodiments.

FIG. 1P-3 is a cross-sectional view illustrating the semiconductor device structure along a sectional line III-III′ in FIG. 1P-1, in accordance with some embodiments.

FIG. 1Q-1 is a top view of the semiconductor device structure of FIG. 1Q, in accordance with some embodiments.

FIG. 1Q-2 is a cross-sectional view illustrating the semiconductor device structure along a sectional line II-II′ in FIG. 1Q-1, in accordance with some embodiments.

FIG. 1Q-3 is a cross-sectional view illustrating the semiconductor device structure along a sectional line III-III′ in FIG. 1Q-1, in accordance with some embodiments.

FIGS. 2A-2F are cross-sectional views of various stages of a process for forming a semiconductor device structure, in accordance with some embodiments.

FIG. 2C-1 is a top view of the semiconductor device structure of FIG. 2C, in accordance with some embodiments.

FIG. 2F-1 is a top view of the semiconductor device structure of FIG. 2F, in accordance with some embodiments.

FIG. 2F-2 is a cross-sectional view illustrating the semiconductor device structure along a sectional line II-II′ in FIG. 2F-1, in accordance with some embodiments.

FIG. 2F-3 is a cross-sectional view illustrating the semiconductor device structure along a sectional line III-III′ in FIG. 2F-1, in accordance with some embodiments.

FIG. 3 is a cross-sectional view of one of stages of a process for forming a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” or “about” in the description, such as in “substantially flat” or in “substantially coplanar”, etc., will be understood by the person skilled in the art. Where applicable, the term “substantially” may also include embodiments with “entirely”, “completely”, “all”, etc. The term “about” in conjunction with a specific distance or size is to be interpreted so as not to exclude insignificant deviation from the specified distance or size. The term “substantially” or “about” may be varied in different technologies and be in the deviation range understood by the skilled in the art. For example, the term “substantially” or “about” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure. Source/drain structure(s) may refer to a source or a drain, individually or collectively dependent upon the context.

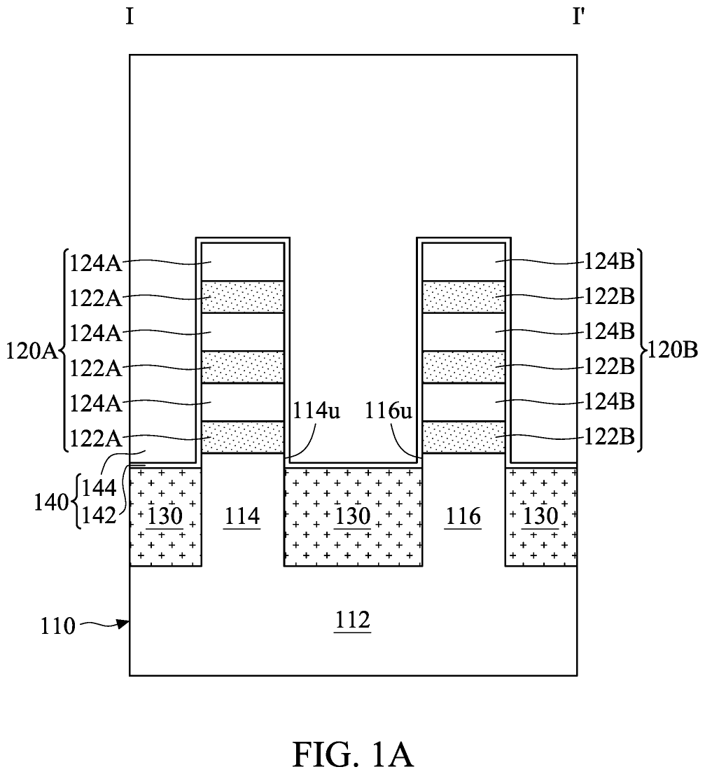

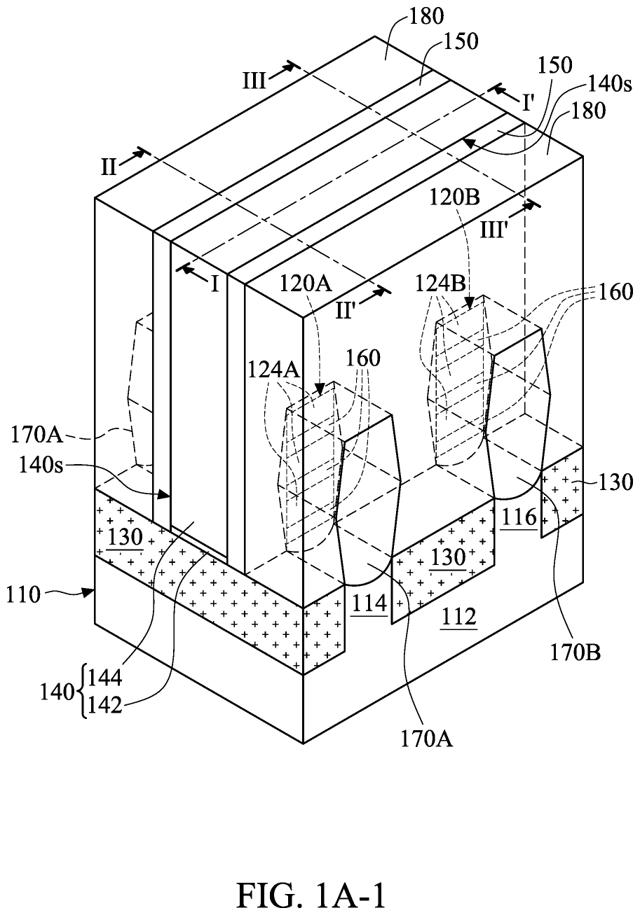

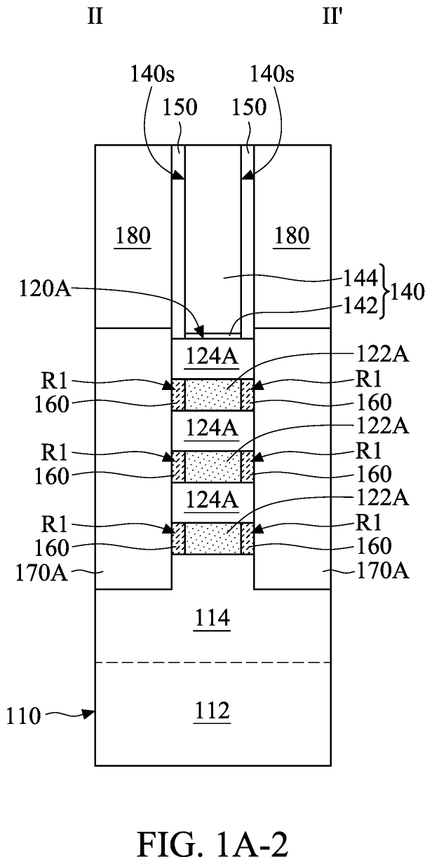

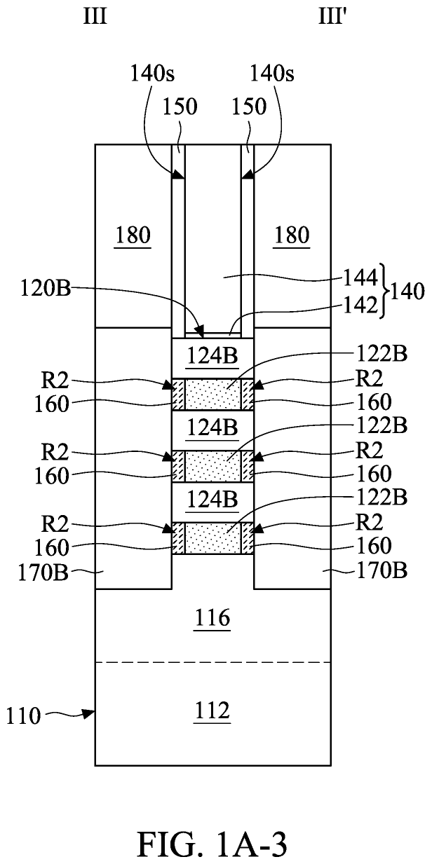

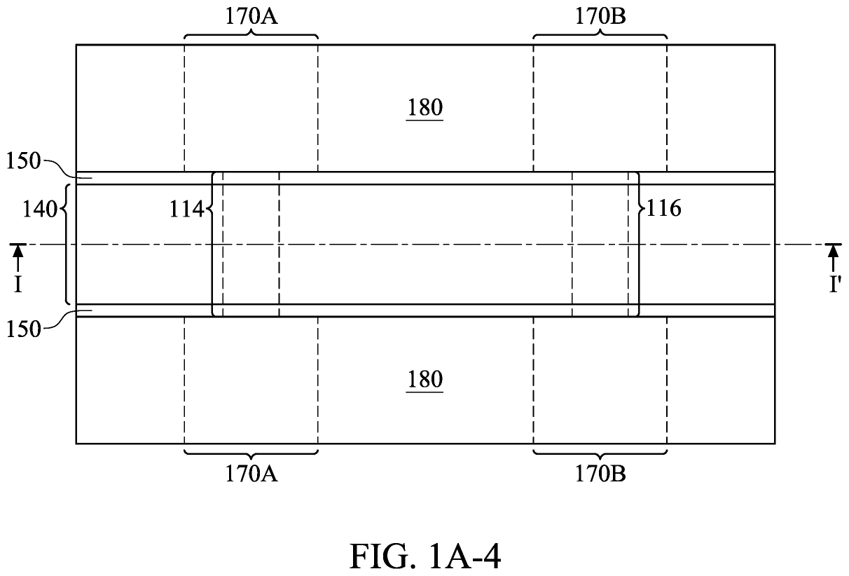

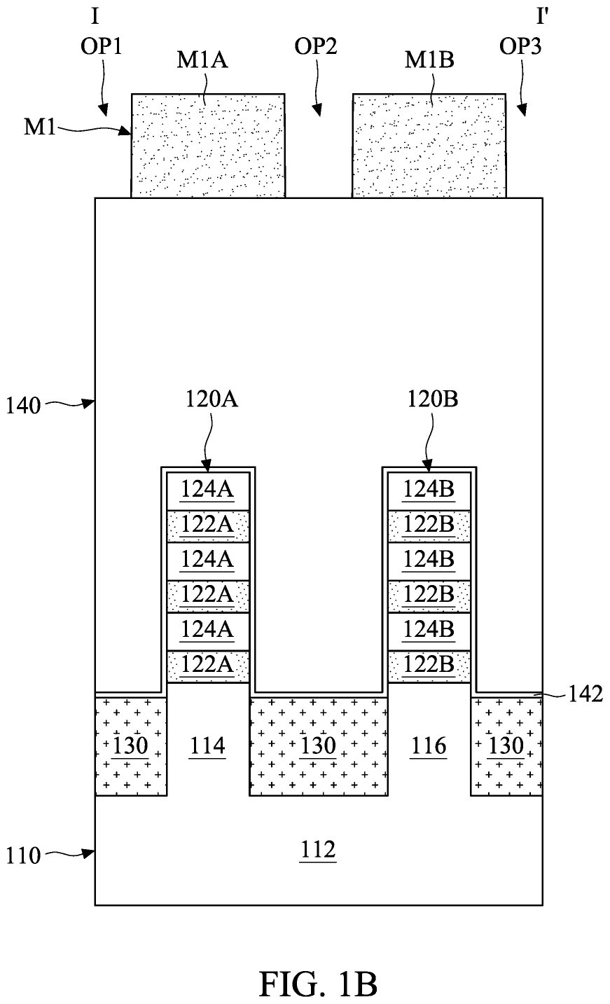

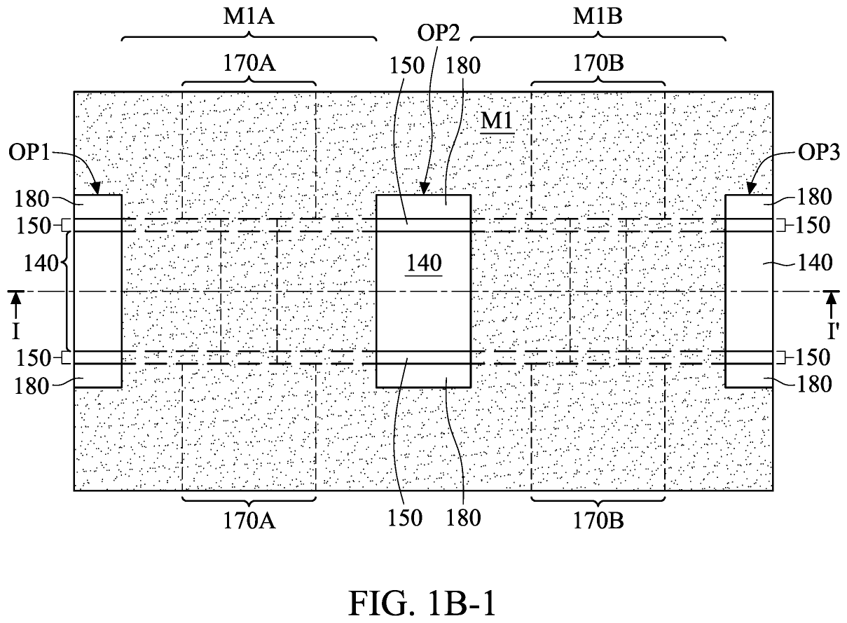

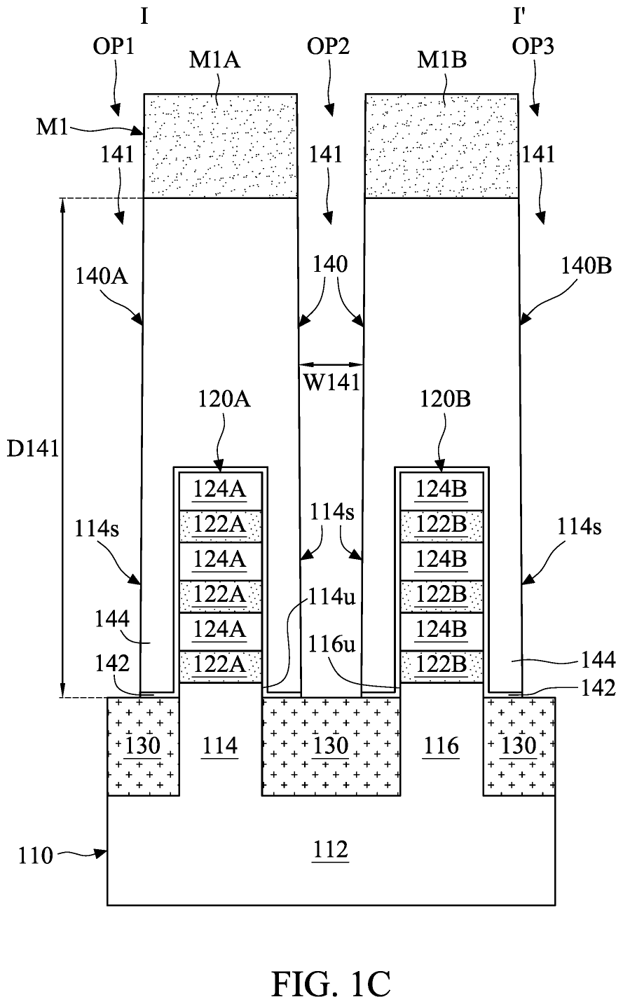

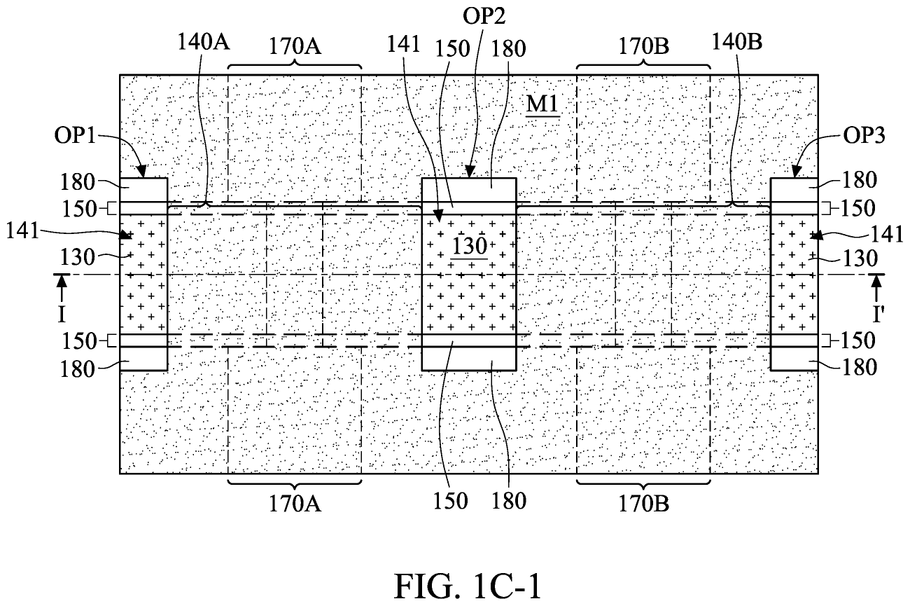

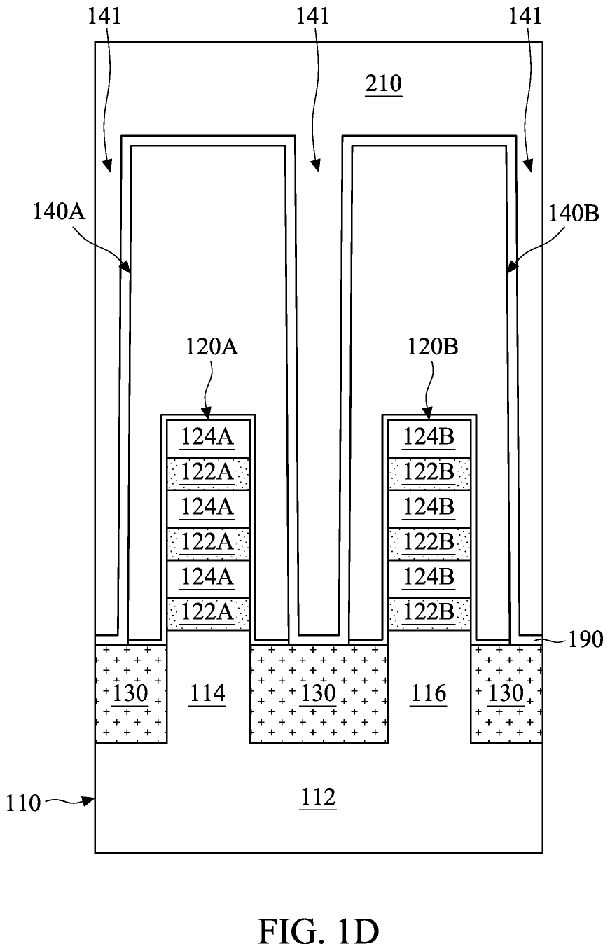

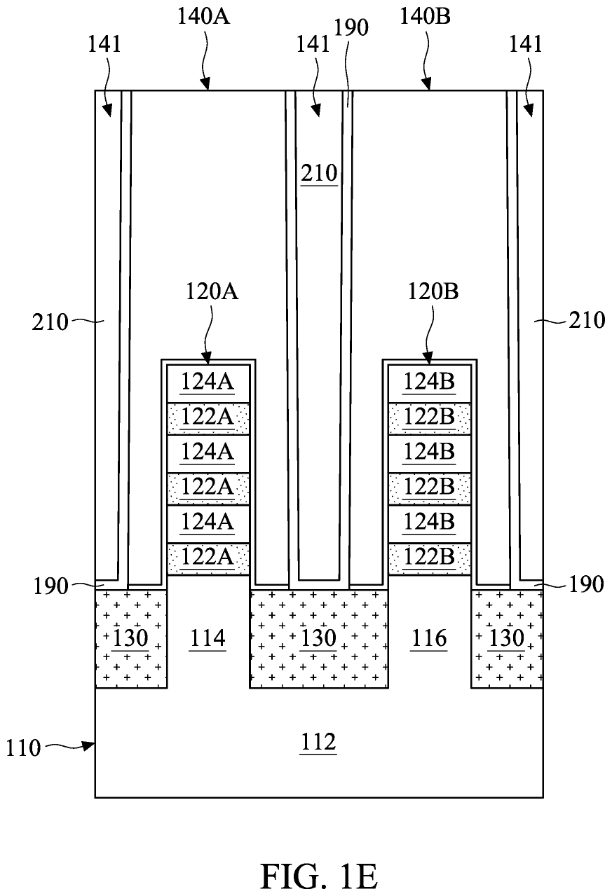

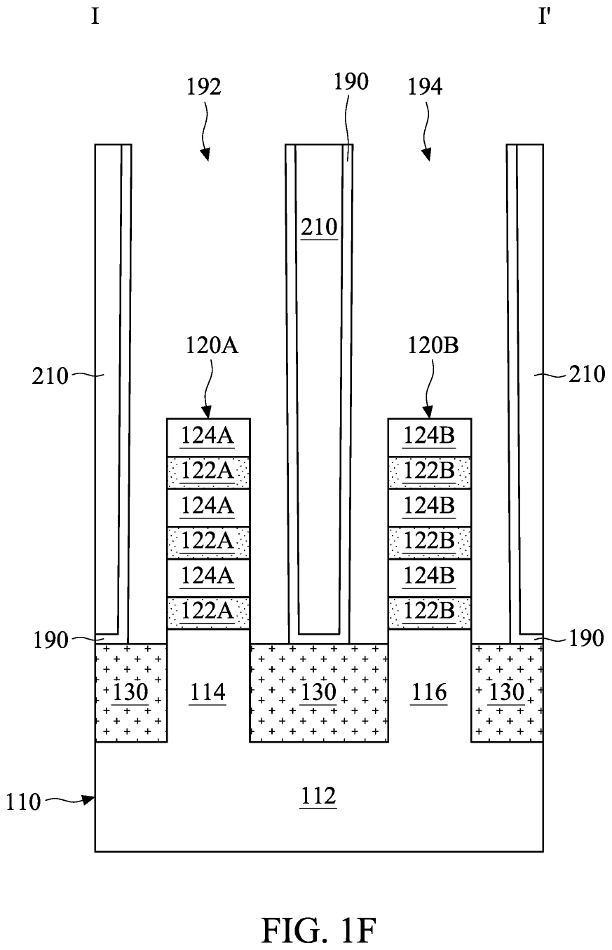

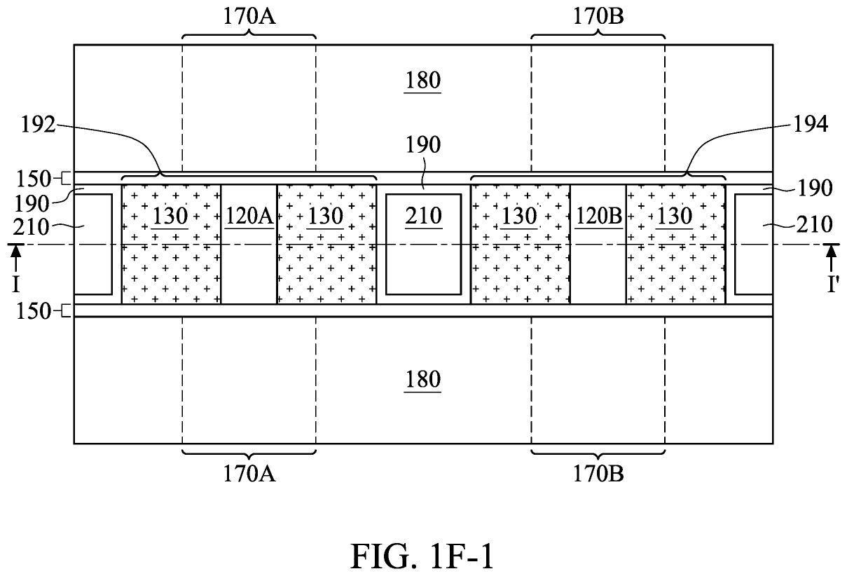

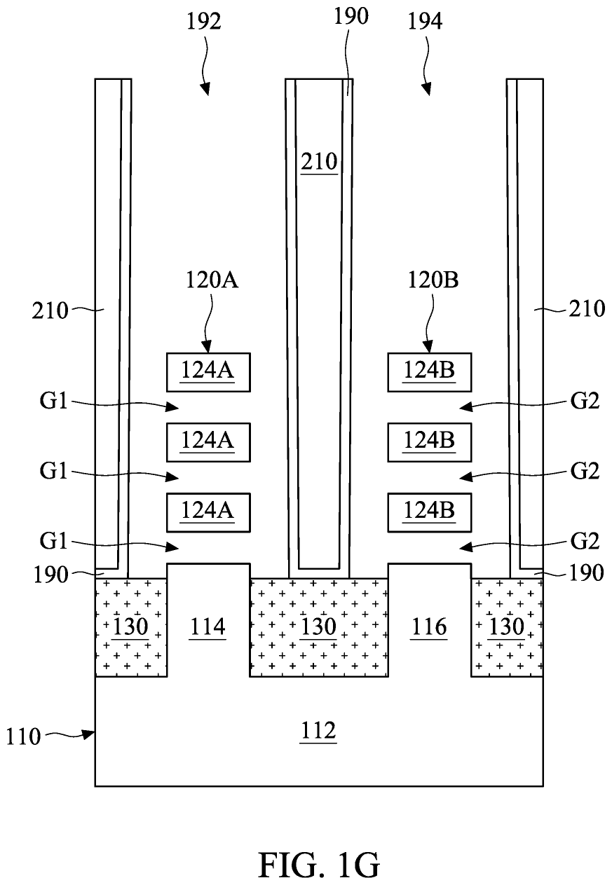

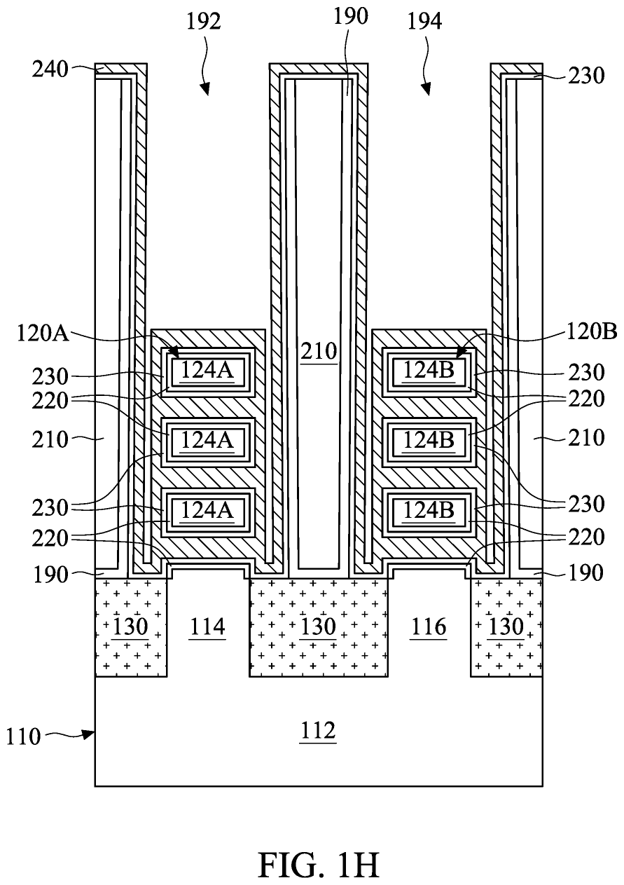

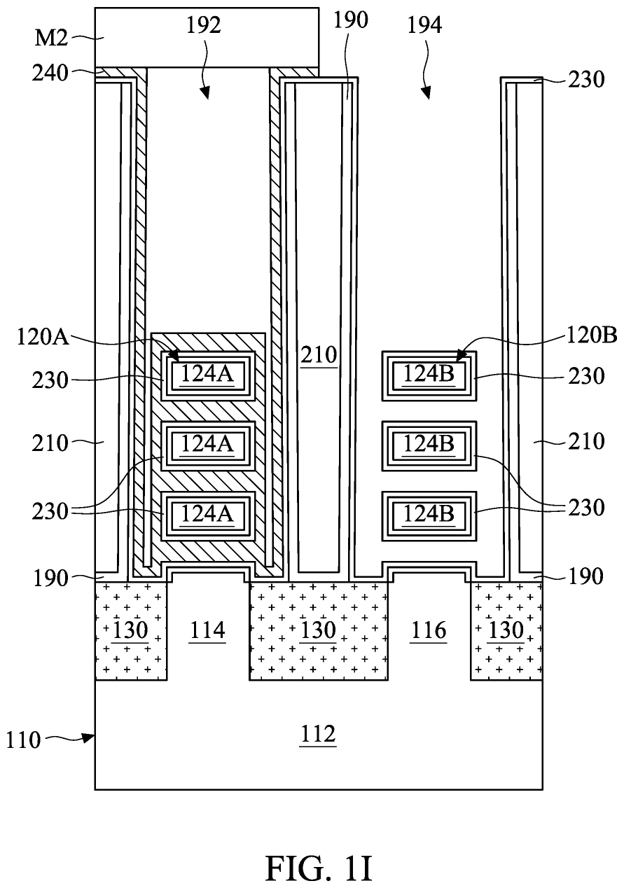

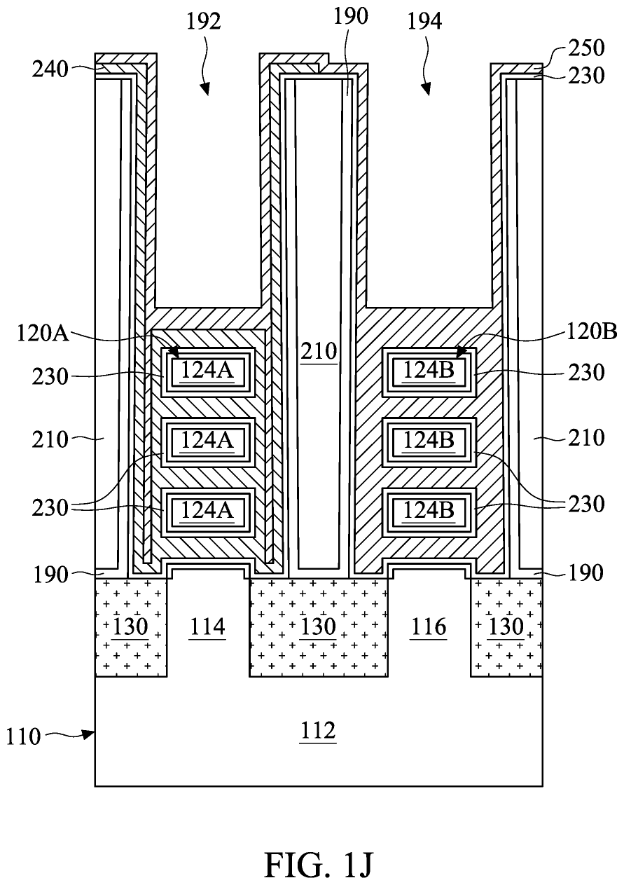

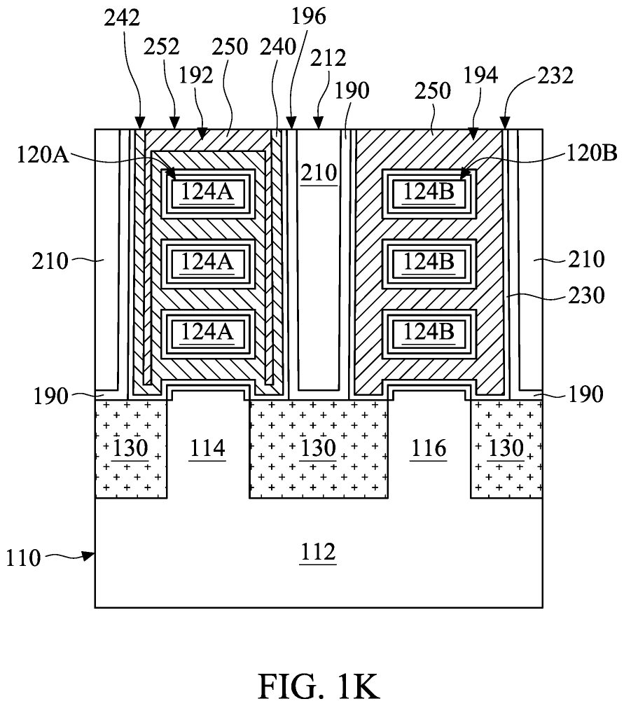

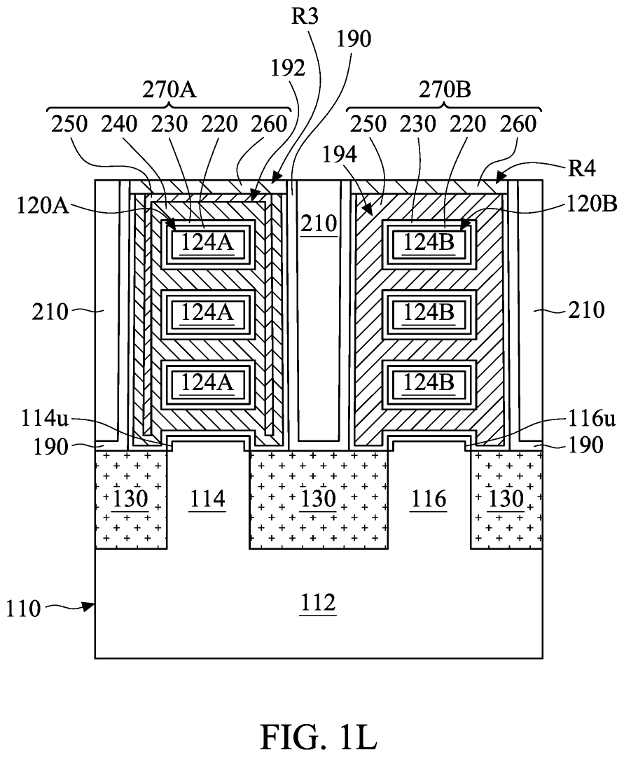

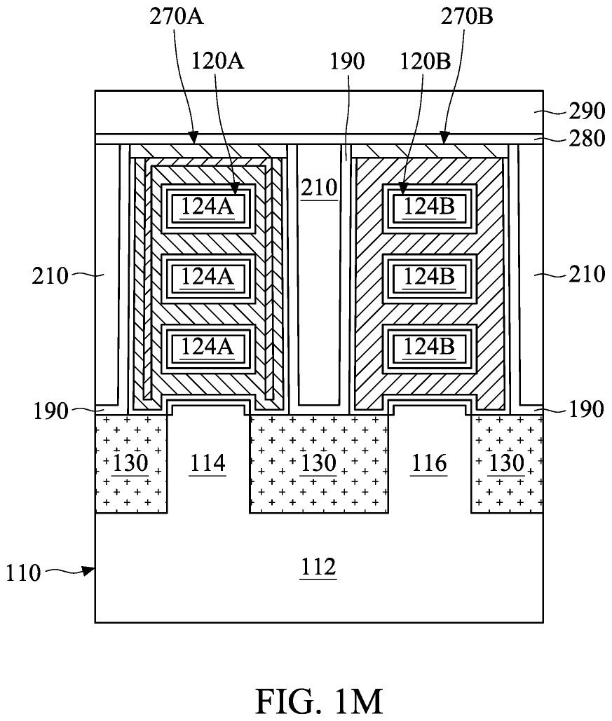

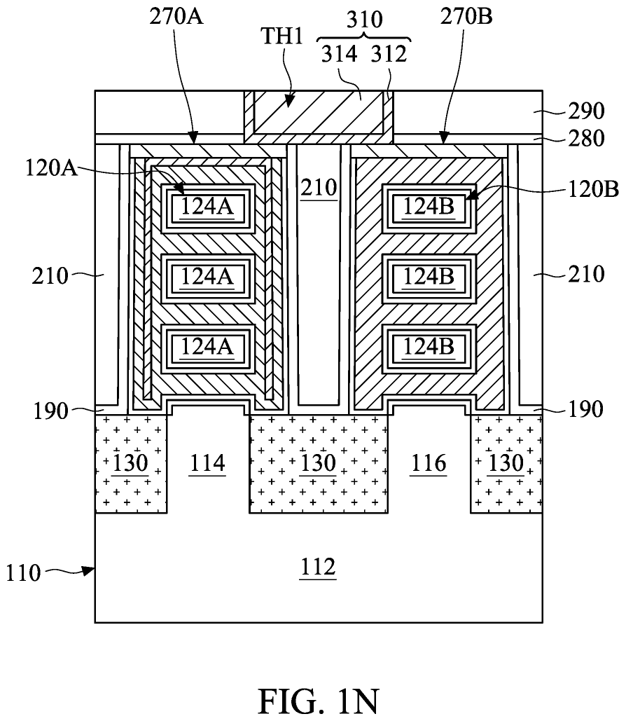

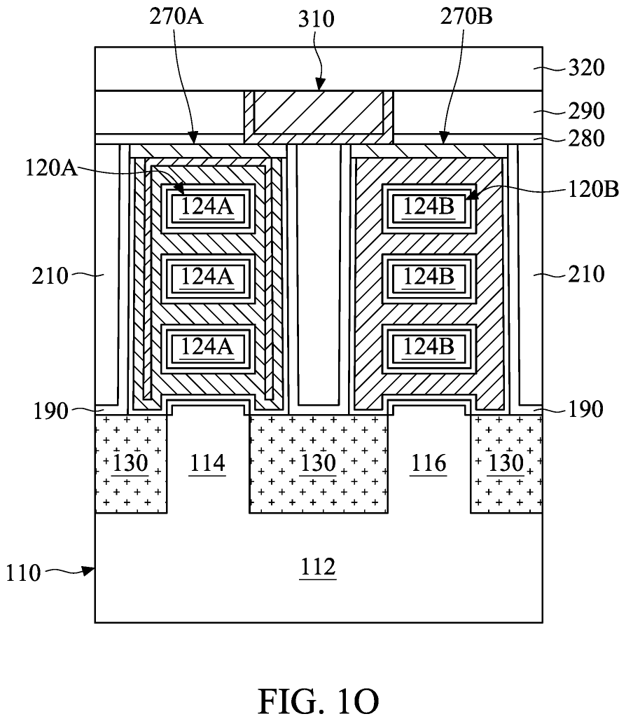

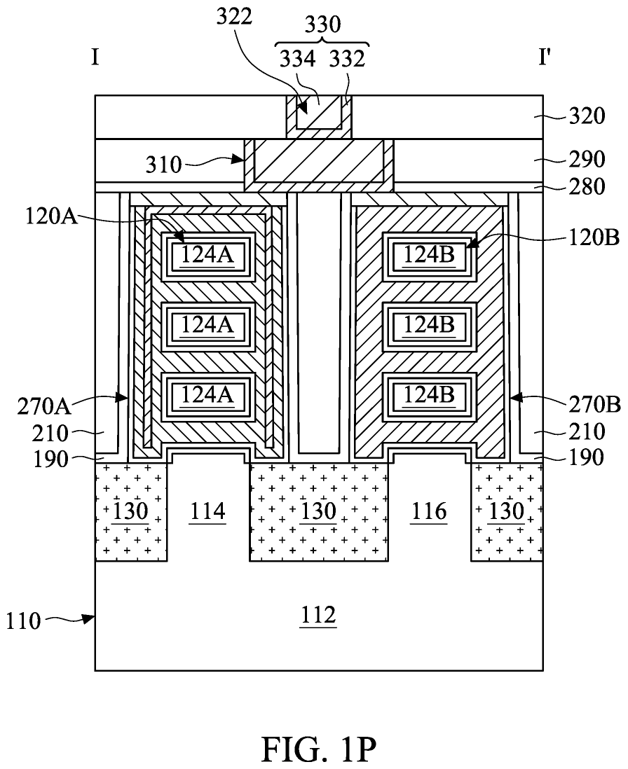

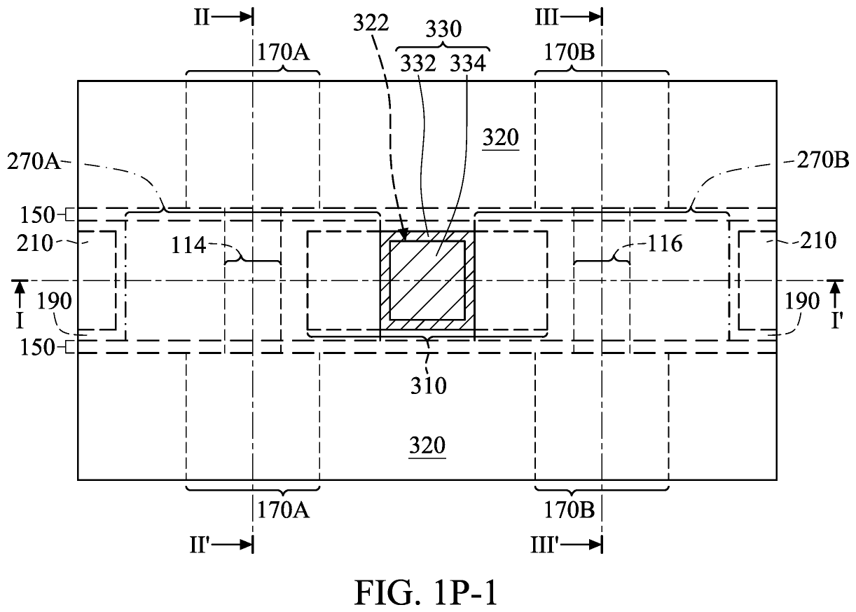

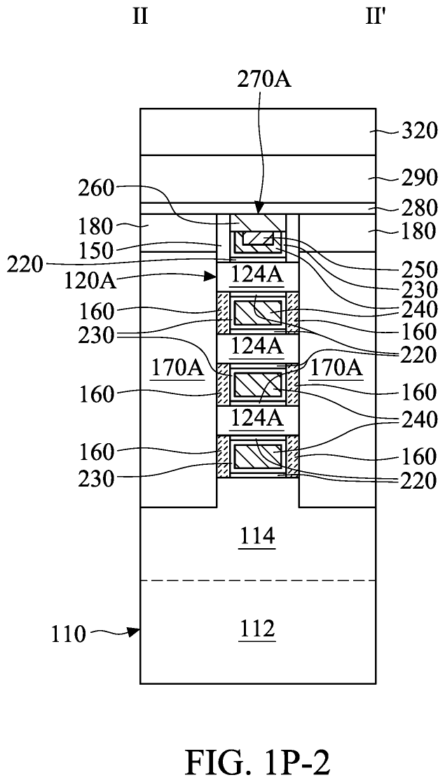

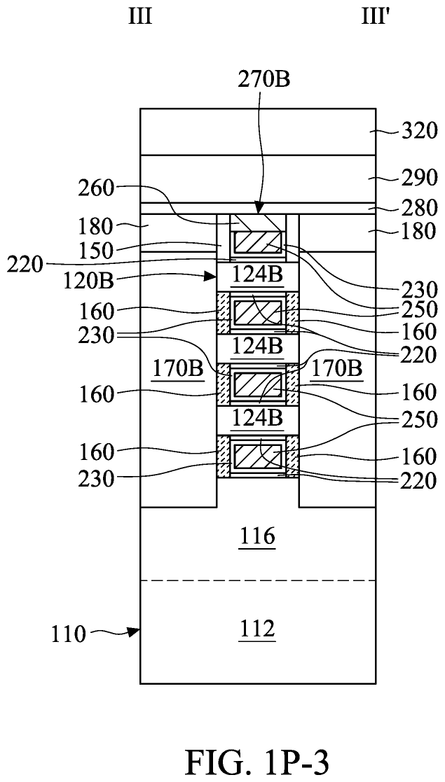

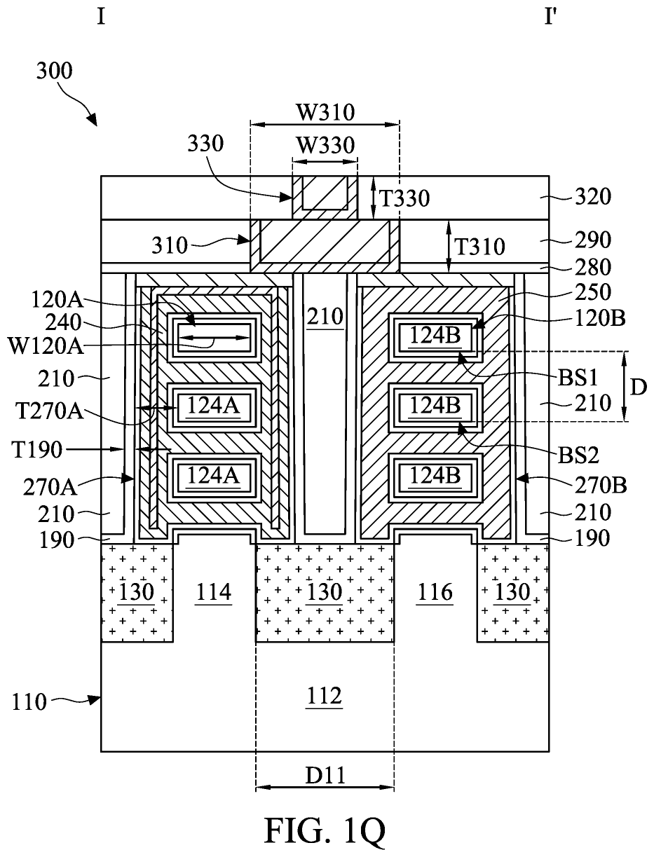

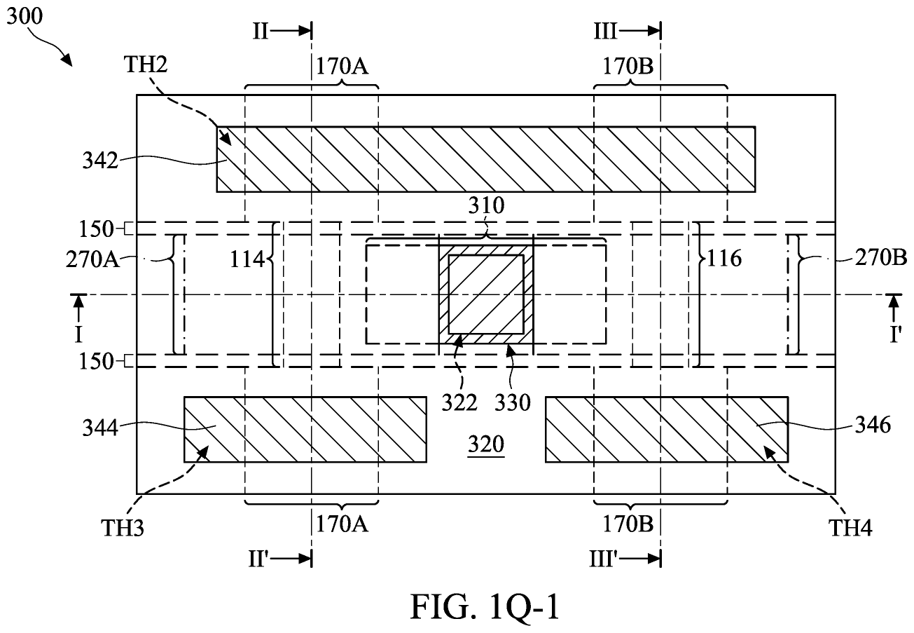

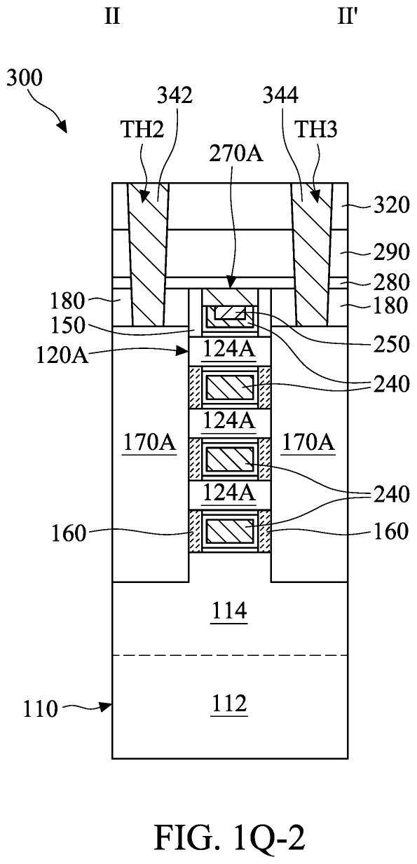

FIGS. 1A-1Q are cross-sectional views of various stages of a process for forming a semiconductor device structure, in accordance with some embodiments. FIG. 1A-1 is a perspective view of the semiconductor device structure of FIG. 1A, in accordance with some embodiments.

As shown in FIGS. 1A and 1A-1, a substrate 110 is provided, in accordance with some embodiments. The substrate 110 has a base 112 and fins 114 and 116, in accordance with some embodiments. The fins 114 and 116 are over the base 112, in accordance with some embodiments.

The substrate 110 includes, for example, a semiconductor substrate. The semiconductor substrate includes, for example, a semiconductor wafer (such as a silicon wafer) or a portion of a semiconductor wafer. In some embodiments, the substrate 110 is made of an elementary semiconductor material including silicon or germanium in a single crystal, polycrystal, or amorphous structure.

In some other embodiments, the substrate 110 is made of a compound semiconductor, such as silicon carbide, gallium arsenide, gallium phosphide, indium phosphide, and/or indium arsenide, an alloy semiconductor, such as SiGe and/or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown). The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to define active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

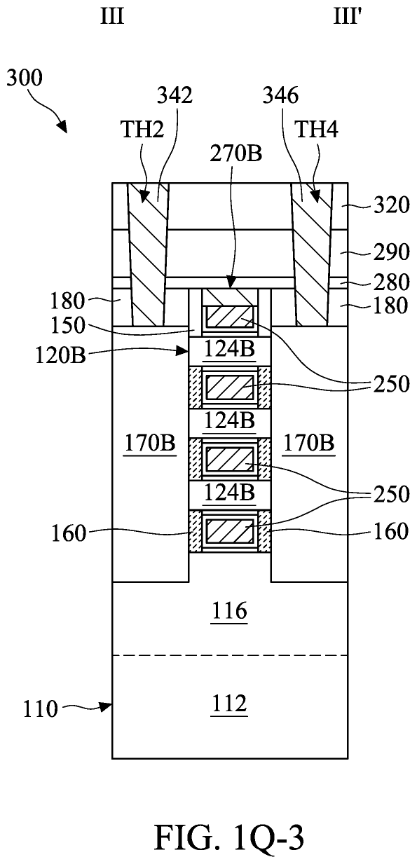

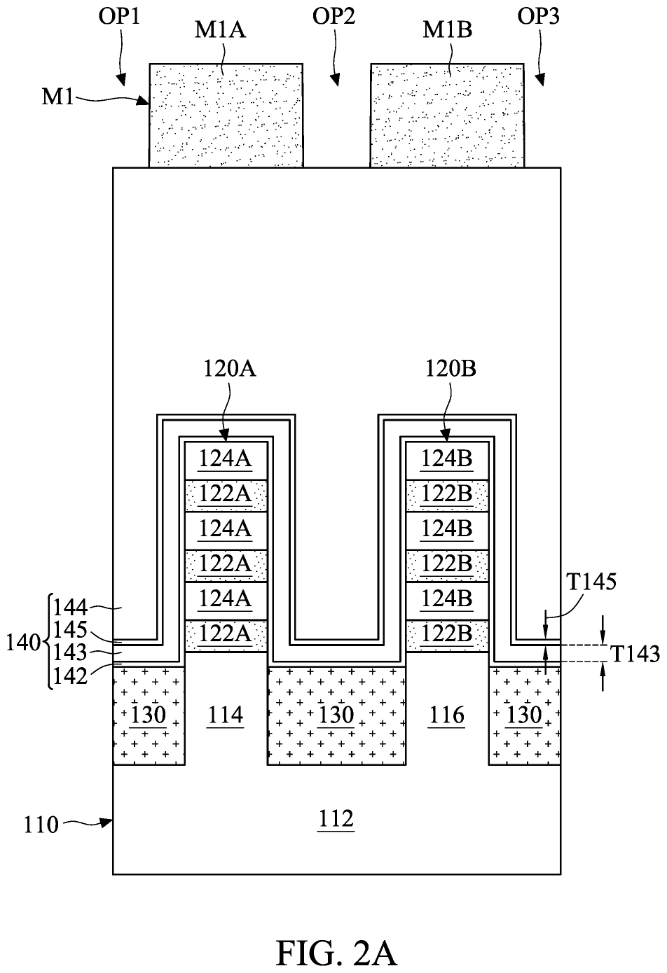

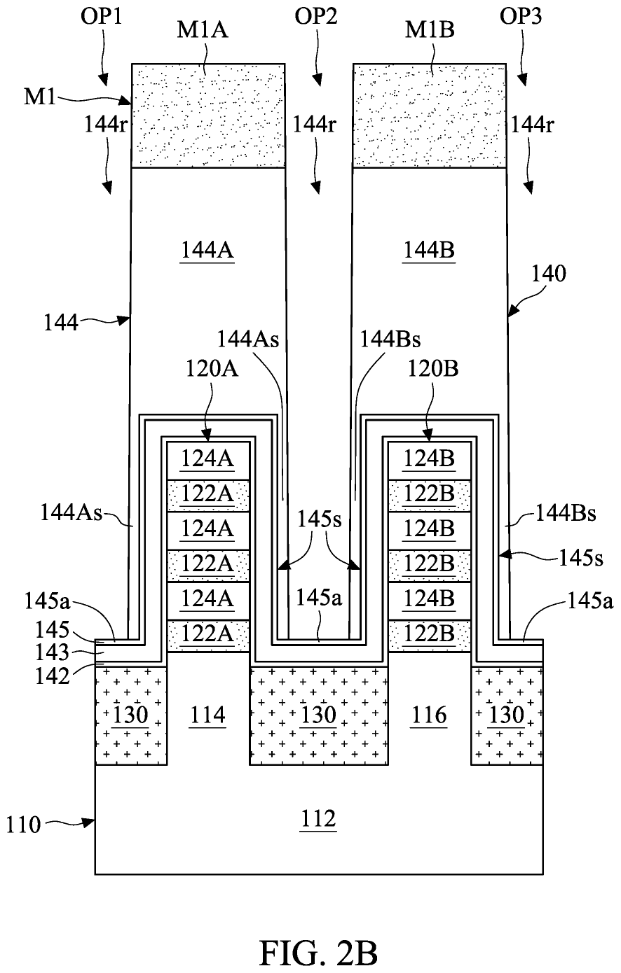

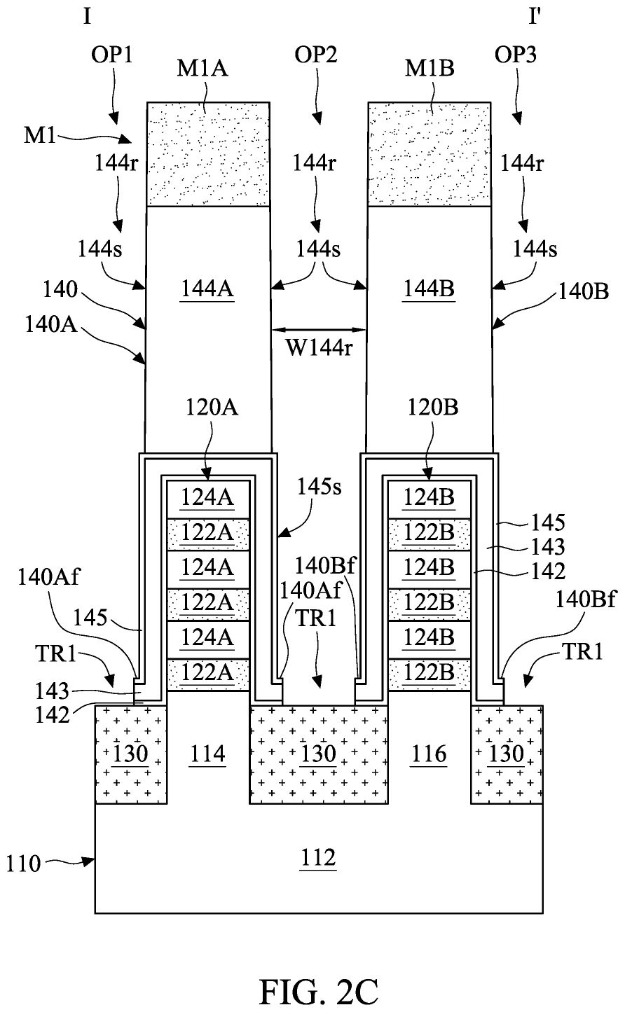

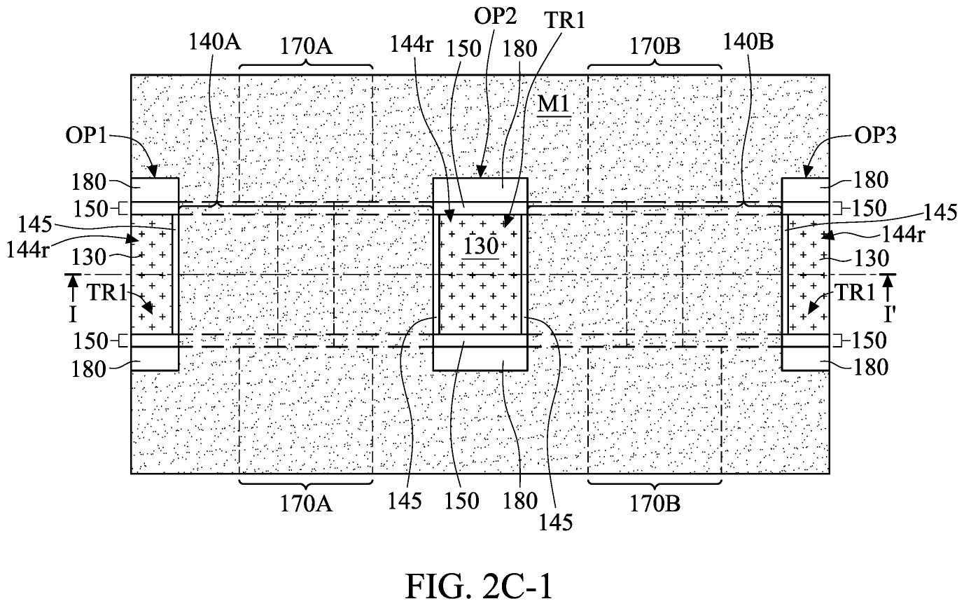

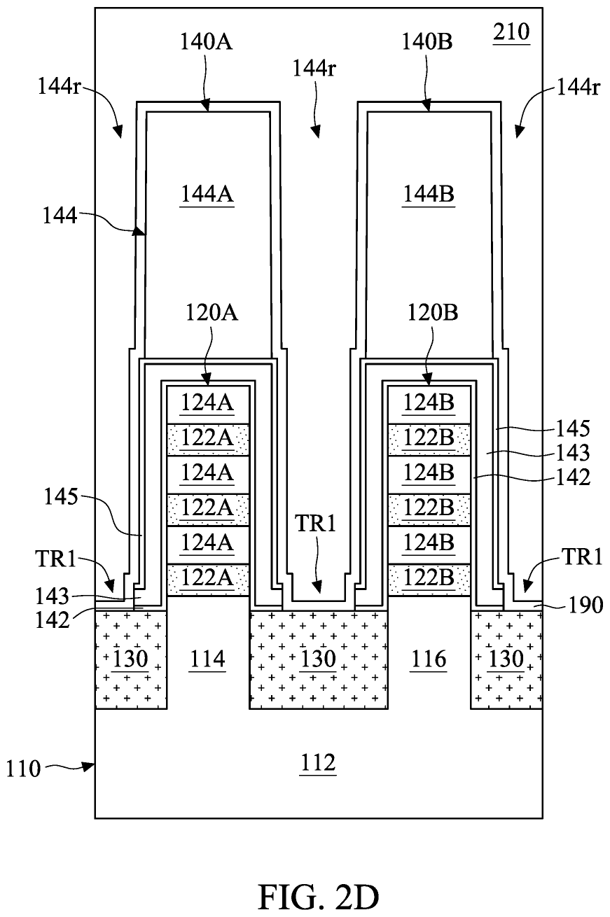

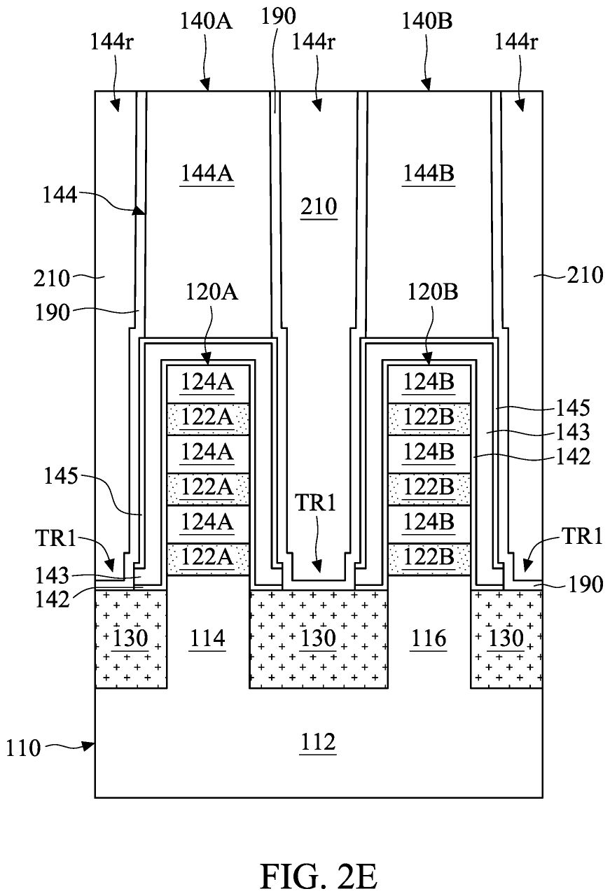

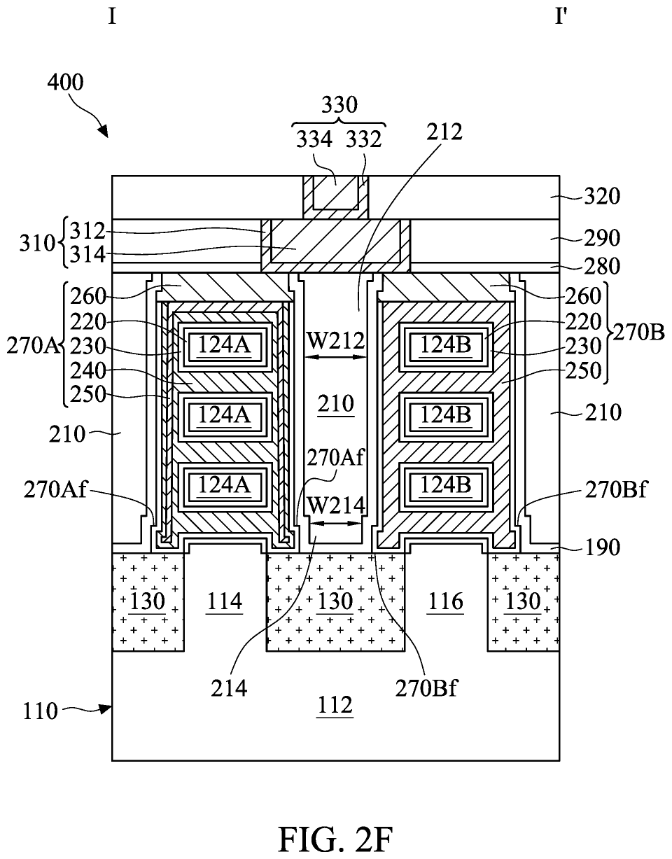

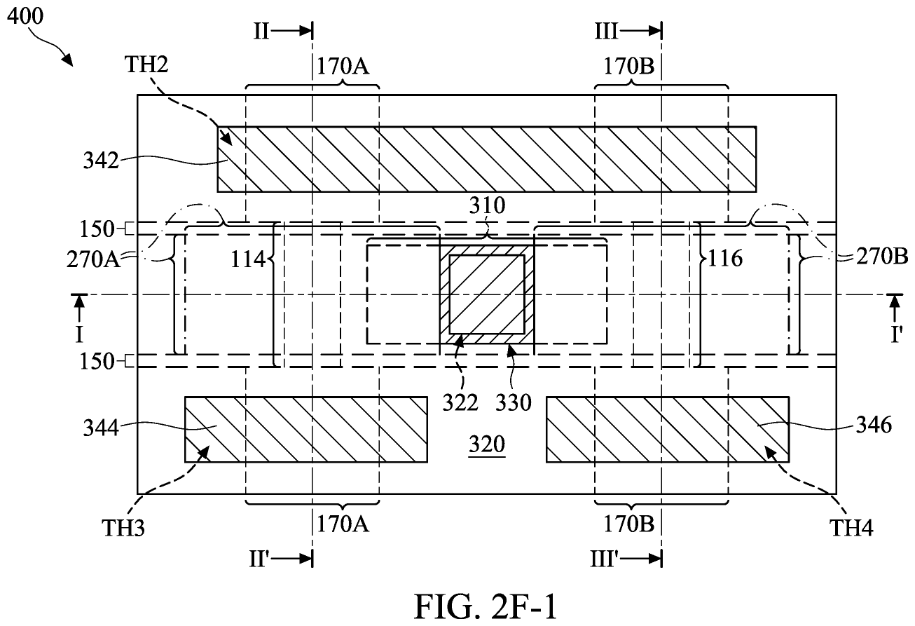

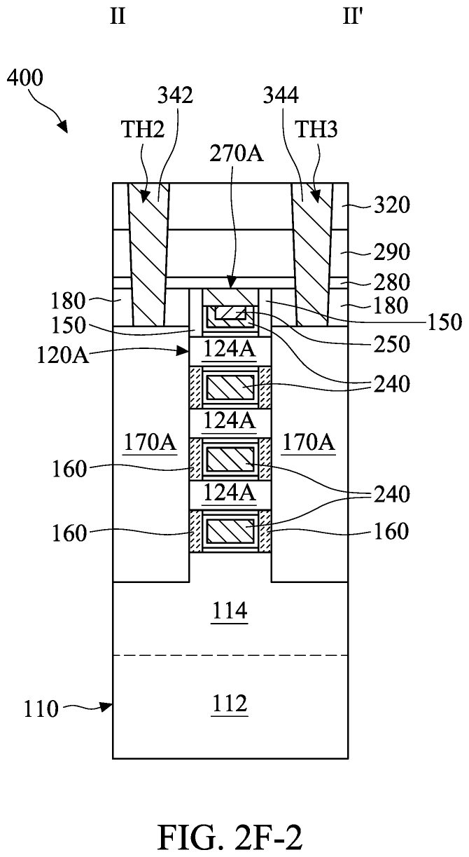

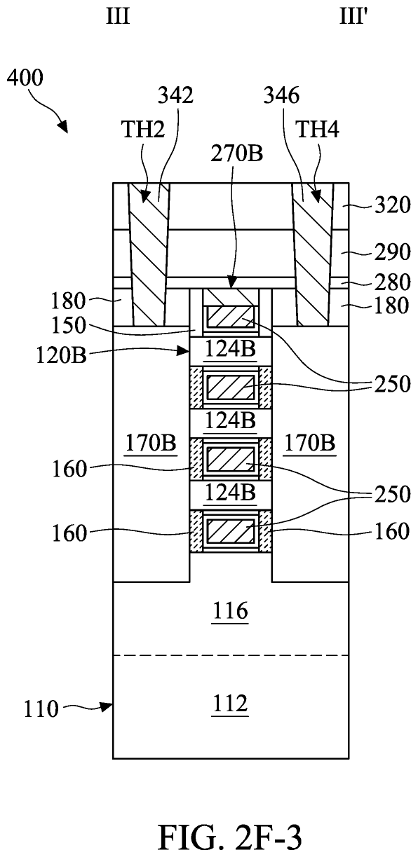

FIG. 1A-2 is a cross-sectional view illustrating the semiconductor device structure along a sectional line II-II′ in FIG. 1A-1, in accordance with some embodiments. FIG. 1A-3 is a cross-sectional view illustrating the semiconductor device structure along a sectional line III-III′ in FIG. 1A-1, in accordance with some embodiments.

As shown in FIGS. 1A, 1A-1, 1A-2, and 1A-3, nanostructure stacks 120A and 120B are formed over the fins 114 and 116 respectively, in accordance with some embodiments. The nanostructure stack 120A includes sacrificial nanostructures 122A and channel nanostructures 124A, in accordance with some embodiments. The sacrificial nanostructures 122A and the channel nanostructures 124A are alternately arranged as illustrated in FIG. 1A, in accordance with some embodiments.

It should be noted that, for the sake of simplicity, FIG. 1A shows three sacrificial nanostructures 122A and three channel nanostructures 124A for illustration, but does not limit the invention thereto. In some embodiments, the number of the sacrificial nanostructures 122A or the channel nanostructures 124A is between 2 and 10.

The sacrificial nanostructures 122A are made of a first material, such as a first semiconductor material, in accordance with some embodiments. The channel nanostructures 124A are made of a second material, such as a second semiconductor material, in accordance with some embodiments.

The first material is different from the second material, in accordance with some embodiments. The first material has an etch selectivity with respect to the second material, in accordance with some embodiments. In some embodiments, the sacrificial nanostructures 122A are made of SiGe, and the channel nanostructures 124A are made of Si.

In some other embodiments, the sacrificial nanostructures 122A or the channel nanostructures 124A are made of other materials such as germanium, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or a combination thereof.

The channel nano structures 124A, the fin 114, and the base 112 are made of the same material such as Si, and the sacrificial nanostructures 122A and the fin 114 (or the base 112) are made of different materials, in accordance with some embodiments. In some other embodiments, the sacrificial nanostructures 122A, the channel nanostructures 124A, and the fin 114 (or the base 112) are made of different materials, in accordance with some embodiments. The sacrificial nanostructures 122A and the channel nanostructures 124A are formed using a molecular beam epitaxy (MBE) process, a metal-organic chemical vapor deposition (MOCVD) process, and/or another suitable epitaxial growth process.

The nanostructure stack 120B includes sacrificial nanostructures 122B and channel nanostructures 124B, in accordance with some embodiments. The sacrificial nanostructures 122B and the channel nanostructures 124B are alternately arranged as illustrated in FIG. 1A, in accordance with some embodiments.

It should be noted that, for the sake of simplicity, FIG. 1A shows three sacrificial nanostructures 122B and three channel nanostructures 124B for illustration, but does not limit the invention thereto. In some embodiments, the number of the sacrificial nanostructures 122B or the channel nanostructures 124B is between 2 and 10.

The sacrificial nanostructures 122B are made of a first material, such as a first semiconductor material, in accordance with some embodiments. The channel nanostructures 124B are made of a second material, such as a second semiconductor material, in accordance with some embodiments.

The first material is different from the second material, in accordance with some embodiments. The first material has an etch selectivity with respect to the second material, in accordance with some embodiments. In some embodiments, the sacrificial nanostructures 122B are made of SiGe, and the channel nanostructures 124B are made of Si.

In some other embodiments, the sacrificial nanostructures 122B or the channel nanostructures 124B are made of other materials such as germanium, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or a combination thereof.

The channel nanostructures 124B, the fin 116, and the base 112 are made of the same material such as Si, and the sacrificial nanostructures 122B and the fin 116 (or the base 112) are made of different materials, in accordance with some embodiments. In some other embodiments, the sacrificial nanostructures 122B, the channel nanostructures 124B, and the fin 116 (or the base 112) are made of different materials, in accordance with some embodiments. The sacrificial nanostructures 122A and 122B are made of the same material such as SiGe, in accordance with some embodiments. The channel nanostructures 124A and 124B are made of the same material such as Si, in accordance with some embodiments.

The sacrificial nanostructures 122B and the channel nanostructures 124B are formed using a molecular beam epitaxy (MBE) process, a metal-organic chemical vapor deposition (MOCVD) process, and/or another suitable epitaxial growth process.

As shown in FIGS. 1A and 1A-1, an isolation layer 130 is formed over the base 112, in accordance with some embodiments. The isolation layer 130 surrounds the fins 114 and 116, in accordance with some embodiments. The isolation layer 130 is made of oxide (such as silicon oxide), fluorosilicate glass (FSG), a low-k dielectric material, and/or another suitable dielectric material. The isolation layer 130 may be formed by an atomic layer deposition (ALD) process, a chemical vapor deposition (CVD) process, or another applicable process.

As shown in FIGS. 1A and 1A-1, a gate stack structure 140 is formed over the fins 114 and 116, the nanostructure stacks 120A and 120B, and the isolation layer 130, in accordance with some embodiments. The gate stack structure 140 is wrapped around the nanostructure stacks 120A and 120B and upper portions 114u and 116u of the fins 114 and 116, in accordance with some embodiments.

The gate stack structure 140 includes a gate dielectric layer 142 and a semiconductor layer 144, in accordance with some embodiments. The gate dielectric layer 142 and the semiconductor layer 144 are sequentially stacked over the fins 114 and 116 and the nanostructure stacks 120A and 120B, in accordance with some embodiments.

The gate dielectric layer 142 conformally covers the fins 114 and 116, the nanostructure stacks 120A and 120B, and the isolation layer 130, in accordance with some embodiments. The gate dielectric layer 142 is made of an insulating material, such as oxide (e.g., silicon oxide), in accordance with some embodiments. The semiconductor layer 144 is made of a semiconductor material (e.g. polysilicon) or a conductive material (e.g., metal or alloy), in accordance with some embodiments.

As shown in FIGS. 1A-1, 1A-2, and 1A-3, a spacer layer 150 is formed over sidewalls 140s of the gate stack structure 140, in accordance with some embodiments. In some embodiments, as shown in FIGS. 1A-1, 1A-2, and 1A-3, the spacer layer 150 is a single-layered structure. In some other embodiments (not shown), the spacer layer 150 is a multi-layered structure. The spacer layer 150 includes layers, in accordance with some embodiments. The layers are made of different materials, in accordance with some embodiments.

In some embodiments, the spacer layer 150 is made of a nitride-containing insulating material or a carbon-containing insulating material, in accordance with some embodiments. The spacer layer 150 is made of silicon nitride (SiN), silicon oxynitride (SiON), silicon oxycarbide (SiOC), silicon oxycarbonitride (SiOCN), or silicon carbonitride (SiCN), in accordance with some embodiments.

The spacer layer 150 is formed using a deposition process and an etching process, in accordance with some embodiments. The deposition process includes a chemical vapor deposition (CVD) process, an atomic layer deposition (ALD) process, or a physical vapor deposition (PVD) process, in accordance with some embodiments.

As shown in FIG. 1A-2 and, portions of the sacrificial nanostructures 122A are removed to form recesses R1 in the nanostructure stack 120A, in accordance with some embodiments. The recess R1 is surrounded by the corresponding sacrificial nanostructure 122A and the corresponding channel nanostructures 124A, in accordance with some embodiments.

As shown in FIG. 1A-3, portions of the sacrificial nanostructures 122B are removed to form recesses R2 in the nanostructure stack 120B, in accordance with some embodiments. The recess R2 is surrounded by the corresponding sacrificial nanostructure 122B and the corresponding channel nanostructures 124B, in accordance with some embodiments. The removal process includes an etching process, such as an isotropic etching process (e.g., a dry etching process or a wet etching process), in accordance with some embodiments.

As shown in FIGS. 1A-1, 1A-2, and 1A-3, an inner spacer layer 160 is formed in the recesses R1 and R2, in accordance with some embodiments. In some embodiments, the inner spacer layer 160 is made of an oxide-containing insulating material, such as silicon oxide.

In some other embodiments, the inner spacer layer 160 is made of a nitride-containing insulating material, such as silicon nitride (SiN), silicon oxynitride (SiON), silicon oxycarbonitride (SiOCN), or silicon carbonitride (SiCN). The inner spacer layer 160 is formed using a deposition process and an etching process, in accordance with some embodiments. The deposition process includes a chemical vapor deposition process or a physical vapor deposition process, in accordance with some embodiments.

FIG. 1A-4 is a top view of the semiconductor device structure of FIG. 1A, in accordance with some embodiments. FIG. 1A is a cross-sectional view illustrating the semiconductor device structure along a sectional line I-I′ in FIG. 1A-1 or 1A-4, in accordance with some embodiments.

As shown in FIGS. 1A-1, 1A-2, 1A-3, and 1A-4, source/drain structures 170A are formed over the fin 114, in accordance with some embodiments. The source/drain structures 170A are in direct contact with the fin 114 and the channel nanostructures 124A, in accordance with some embodiments.

In some other embodiments, the source/drain structures 170A are made of a semiconductor material (e.g., silicon) with N-type dopants, such as the Group VA element, in accordance with some embodiments. The Group VA element includes phosphor (P), antimony (Sb), or another suitable Group VA material. The source/drain structures 170A are formed using an epitaxial process, in accordance with some embodiments.

As shown in FIGS. 1A-1, 1A-2, and 1A-3, source/drain structures 170B are formed over the fin 116, in accordance with some embodiments. The source/drain structures 170B are in direct contact with the fin 116 and the channel nanostructures 124B, in accordance with some embodiments.

In some embodiments, the source/drain structures 170B are made of a semiconductor material (e.g., silicon germanium) with P-type dopants, such as the Group IIIA element, in accordance with some embodiments. The Group IIIA element includes boron or another suitable material.

The source/drain structures 170A and 170B are made of different materials, in accordance with some embodiments. The source/drain structures 170A and 170B are formed using different epitaxial growth processes, in accordance with some embodiments.

For example, the formation of the source/drain structures 170A and 170B includes forming a first mask layer (not shown) over the fin 116; forming the source/drain structures 170A over the fin 114; removing the first mask layer; forming a second mask layer (not shown) over the source/drain structures 170A; forming the source/drain structures 170B over the fin 116; and removing the second mask layer.

As shown in FIGS. 1A-1, 1A-2, and 1A-3, a dielectric layer 180 is formed over the source/drain structures 170A and 170B and the isolation layer 130, in accordance with some embodiments. The dielectric layer 180 is wrapped around the gate stack structure 140 and the spacer layer 150, in accordance with some embodiments.

The dielectric layer 180 is made of an oxide-containing insulating material, such as silicon oxide, or a nitride-containing insulating material, such as silicon nitride, silicon oxynitride, silicon oxycarbonitride, or silicon carbonitride, in accordance with some embodiments.

The dielectric layer 180 is formed using a deposition process and a removal process, in accordance with some embodiments. The deposition process includes an atomic layer deposition (ALD) process, a chemical vapor deposition (CVD) process, or another applicable process. The removal process includes a planarization process, such as a chemical mechanical polishing process, in accordance with some embodiments.

In some embodiments, the dielectric layer 180 includes a multi-layered structure. The dielectric layer 180 includes a thin film and a dielectric film over the thin film, in accordance with some embodiments. The thin film is made of a nitride-containing insulating material such as silicon nitride, in accordance with some embodiments.

The dielectric film is made of an oxide-containing insulating material such as silicon oxide, in accordance with some embodiments. The thin film is formed using an atomic layer deposition (ALD) process, in accordance with some embodiments. The dielectric film is formed using a chemical vapor deposition (CVD) process, in accordance with some embodiments.

FIG. 1B-1 is a top view of the semiconductor device structure of FIG. 1B, in accordance with some embodiments. FIG. 1B is a cross-sectional view illustrating the semiconductor device structure along a sectional line I-I′ in FIG. 1B-1, in accordance with some embodiments.

As shown in FIGS. 1B and 1B-1, a mask layer M1 is formed over the gate stack structure 140, in accordance with some embodiments. The mask layer M1 has openings OP1, OP2, and OP3, in accordance with some embodiments. The openings OP1, OP2, and OP3 expose portions of the gate stack structure 140, in accordance with some embodiments.

The mask layer M1 has portions M1A and M1B, in accordance with some embodiments. The portion M1A is between the openings OP1 and OP2, in accordance with some embodiments. The portion M1B is between the openings OP2 and OP3, in accordance with some embodiments. The mask layer M1 is made of a polymer material such as a photoresist material, in accordance with some embodiments.

FIG. 1C-1 is a top view of the semiconductor device structure of FIG. 1C, in accordance with some embodiments. FIG. 1C is a cross-sectional view illustrating the semiconductor device structure along a sectional line I-I′ in FIG. 1C-1, in accordance with some embodiments. As shown in FIGS. 1C and 1C-1, portions of the gate stack structure 140 are removed through the openings OP1, OP2, and OP3 of the mask layer M1 to form trenches 141 in the gate stack structure 140, in accordance with some embodiments.

The gate stack structure 140 is divided into gate stacks 140A and 140B by the trenches 141, in accordance with some embodiments. The gate stacks 140A and 140B are between the trenches 141, in accordance with some embodiments. The gate stack 140A is wrapped around the nanostructure stack 120A and the upper portion 114u of the fin 114, in accordance with some embodiments. The gate stack 140B is wrapped around the nanostructure stack 120B and the upper portion 116u of the fin 116, in accordance with some embodiments.

In some embodiments, a width W141 of the trench 141 decreases toward the base 112. The width W141 ranges from about 10 nm to about 40 nm, in accordance with some embodiments. In some embodiments, a depth D141 of the trench 141 ranges from about 60 nm to about 80 nm. The aspect ratio of the trench 141 ranges from about 1.5 to about 8, in accordance with some embodiments. The inner walls 114s of the trenches 141 are inclined walls, in accordance with some embodiments.

As shown in FIG. 1D, a protective layer 190 is conformally formed over the gate stacks 140A and 140B and the isolation layer 130, in accordance with some embodiments. The protective layer 190 is used to protect the gate stacks 140A and 140B from oxidation, in accordance with some embodiments.

The protective layer 190 is made of nitrides such as silicon nitride, in accordance with some embodiments. The protective layer 190 is formed using an atomic layer deposition (ALD) process, a chemical vapor deposition (CVD) process, a physical vapor deposition (PVD) process, or another applicable process.

As shown in FIG. 1D, an isolation structure 210 is formed over the protective layer 190, in accordance with some embodiments. The isolation structure 210 is made of oxide (such as silicon oxide), fluorosilicate glass (FSG), a low-k dielectric material, and/or another suitable dielectric material. The isolation structure 210 may be formed by an atomic layer deposition (ALD) process, a chemical vapor deposition (CVD) process, or another applicable process.

As shown in FIG. 1E, top portions of the protective layer 190 and the isolation structure 210, which are outside of the trenches 141 of the gate stack structure 140, are removed, in accordance with some embodiments. The removal process includes a planarization process such as a chemical mechanical polishing (CMP) process, in accordance with some embodiments.

FIG. 1F-1 is a top view of the semiconductor device structure of FIG. 1F, in accordance with some embodiments. FIG. 1F is a cross-sectional view illustrating the semiconductor device structure along a sectional line I-I′ in FIG. 1F-1, in accordance with some embodiments.

As shown in FIGS. 1F and 1F-1, the gate stacks 140A and 140B are removed to form recesses 192 and 194 in the protective layer 190, the dielectric layer 180, and the spacer layer 150, in accordance with some embodiments. The removal process includes an etching process such as a dry etching process or a wet etching process, in accordance with some embodiments.

As shown in FIGS. 1F and 1G, the sacrificial nanostructures 122A and 122B are removed through the recesses 192 and 194 of the protective layer 190 respectively, in accordance with some embodiments. The removal process forms gaps G1 between the nanostructures 124A and the fin 114, in accordance with some embodiments.

The removal process forms gaps G2 between the nanostructures 124B and the fin 116, in accordance with some embodiments. The removal process includes an etching process such as a wet etching process or a dry etching process, in accordance with some embodiments.

As shown in FIG. 1H, an interfacial layer 220 is conformally formed over the fins 114 and 116 and the nanostructures 124A and 124B, in accordance with some embodiments. The interfacial layer 220 is made of an insulating material such as oxide (e.g., silicon oxide), in accordance with some embodiments. The interfacial layer 220 is formed using an oxidation process, in accordance with some embodiments.

As shown in FIG. 1H, a gate dielectric layer 230 is conformally formed over the interfacial layer 220, the isolation layer 130, the protective layer 190, and the isolation structure 210, in accordance with some embodiments. The gate dielectric layer 230 is made of a high-K material, such as HfO₂, La₂O₃, CaO, ZrO₂, HfZrO₂, or Al₂O₃, in accordance with some embodiments. The gate dielectric layer 230 is formed using an atomic layer deposition process or another suitable process.

As shown in FIG. 1H, a work function metal layer 240 is conformally formed over the gate dielectric layer 230, in accordance with some embodiments. The work function metal layer 240 provides a desired work function for transistors to enhance device performance including improved threshold voltage. The work function metal layer 240 is also referred to as an n-type work function metal layer, in accordance with some embodiments. The work function metal layer 240 can be a metal capable of providing a work function value suitable for the device, such as equal to or less than about 4.5 eV.

The work function metal layer 240 is made of metal, metal carbide, metal nitride, or a combination thereof, in accordance with some embodiments. For example, the work function metal layer 240 is made of tantalum, hafnium carbide, zirconium carbide, tantalum nitride, or a combination thereof.

The work function metal layer 240 is formed using a deposition process, in accordance with some embodiments. The deposition process includes a physical vapor deposition process, a chemical vapor deposition process, an atomic layer deposition process, or a combination thereof, in accordance with some embodiments.

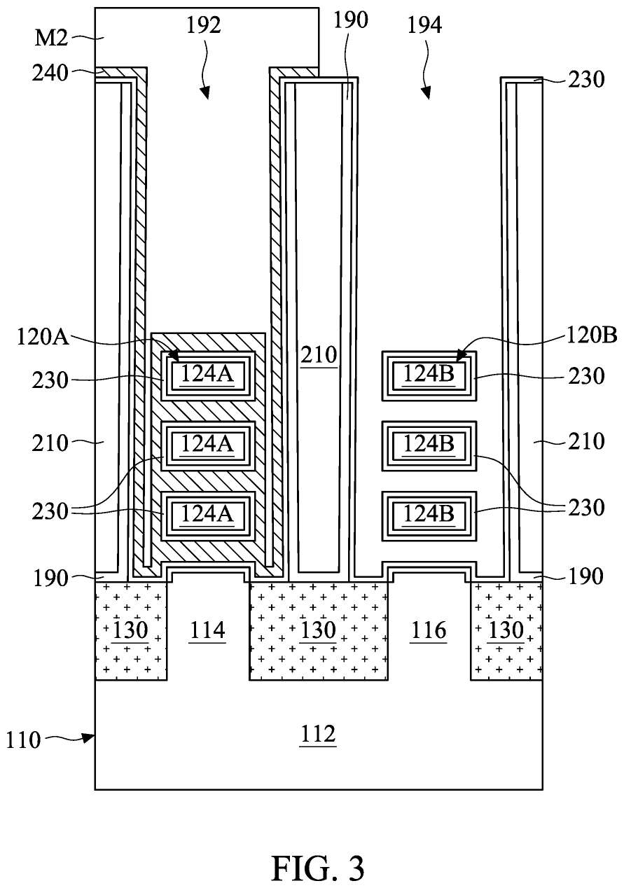

As shown in FIG. 1I, a mask layer M2 is formed over the work function metal layer 240, in accordance with some embodiments. In some other embodiments, as shown in FIG. 3, the mask layer M2 is partially in the recess 192 of the protective layer 190. As shown in FIG. 1I, portions of the work function metal layer 240, which are not covered by the mask layer M2, are removed, in accordance with some embodiments. The removal process includes an etching process such as a dry etching process, in accordance with some embodiments.

As shown in FIG. 1J, a work function metal layer 250 is conformally formed over the gate dielectric layer 230 in the recess 194 of the protective layer 190, in accordance with some embodiments. The work function metal layer 250 is further formed over the work function metal layer 240, in accordance with some embodiments.

The work function metal layer 250 is also referred to as a p-type work function metal layer, in accordance with some embodiments. The work function metal layer 250 provides a desired work function for transistors to enhance device performance including improved threshold voltage. The work function metal layer 250 can be a metal capable of providing a work function value suitable for the device, such as equal to or greater than about 4.8 eV.

The work function metal layer 250 is made of metal, metal carbide, metal nitride, another suitable material, or a combination thereof, in accordance with some embodiments. For example, the work function metal layer 250 is made of titanium, titanium nitride, another suitable material, or a combination thereof.

The work function metal layer 250 is formed using a deposition process, in accordance with some embodiments. The deposition process includes a physical vapor deposition process, a chemical vapor deposition process, an atomic layer deposition process, or a combination thereof, in accordance with some embodiments.

As shown in FIG. 1K, top portions of the protective layer 190, the isolation structure 210, the gate dielectric layer 230, and the work function metal layers 240 and 250, which are outside of the recesses 192 and 194 of the protective layer 190, are removed, in accordance with some embodiments. The removal process includes a planarization process such as a chemical mechanical polishing (CMP) process, in accordance with some embodiments.

After the removal process, top surfaces 196, 212, 232, 242, and 252 of the protective layer 190, the isolation structure 210, the gate dielectric layer 230, and the work function metal layers 240 and 250 are substantially level with each other, in accordance with some embodiments.

As shown in FIG. 1L, top portions of the gate dielectric layer 230 and the work function metal layers 240 and 250 are removed to form recesses R3 and R4 over the nanostructure stacks 120A and 120B, in accordance with some embodiments. The removal process includes an etching process, such as a dry etching process or a wet etching process, in accordance with some embodiments.

As shown in FIG. 1L, a gate electrode layer 260 is formed in the recesses R3 and R4, in accordance with some embodiments. The gate electrode layer 260 is made of W, Co, Al, or another suitable conductive material. The gate electrode layer 260 is formed using an atomic layer deposition process or another suitable process.

The gate electrode layer 260 in the recess R3, the interfacial layer 220, the gate dielectric layer 230, and the work function metal layers 240 and 250 in the recess 192 of the protective layer 190 together form an n-type gate stack 270A, in accordance with some embodiments.

The gate electrode layer 260 in the recess R4, the interfacial layer 220, the gate dielectric layer 230, and the work function metal layer 250 in the recess 194 of the protective layer 190 together form a p-type gate stack 270B, in accordance with some embodiments.

The isolation structure 210 is between the n-type gate stack 270A and the p-type gate stack 270B, in accordance with some embodiments. The isolation structure 210 separates the n-type gate stack 270A from the p-type gate stack 270B, in accordance with some embodiments. The n-type gate stack 270A is wrapped around the nanostructures 124A and the upper portion 114u of the fin 114, in accordance with some embodiments. The p-type gate stack 270B is wrapped around the nanostructures 124B and the upper portion 116u of the fin 116, in accordance with some embodiments.

As shown in FIG. 1M, an etch stop layer 280 is formed over the protective layer 190, the isolation structure 210, the n-type gate stack 270A, and the p-type gate stack 270B, in accordance with some embodiments. The etching stop layer 280 is made of a nitride material such as silicon nitride, in accordance with some embodiments.

As shown in FIG. 1M, a dielectric layer 290 is formed over the etch stop layer 280, in accordance with some embodiments. The dielectric layer 290 is made of an oxide-containing insulating material, such as silicon oxide, or a nitride-containing insulating material, such as silicon nitride, silicon oxynitride, silicon oxycarbonitride, or silicon carbonitride, in accordance with some embodiments.

The dielectric layer 290 is formed using a deposition process, in accordance with some embodiments. The deposition process includes an atomic layer deposition (ALD) process, a chemical vapor deposition (CVD) process, or another applicable process.

As shown in FIG. 1N, portions of the etch stop layer 280 and the dielectric layer 290 are removed to form a through hole TH1, in accordance with some embodiments. As shown in FIG. 1N, a conductive line 310 is formed in the through hole TH1, in accordance with some embodiments. The conductive line 310 is over the n-type gate stack 270A, the p-type gate stack 270B, and the isolation structure 210, in accordance with some embodiments. The conductive line 310 electrically connects the n-type gate stack 270A to the p-type gate stack 270B, in accordance with some embodiments.

The conductive line 310 includes a barrier layer 312 and a conductive layer 314 over the barrier layer 312, in accordance with some embodiments. The barrier layer 312 is made of metal nitrides such as TaN or TiN, in accordance with some embodiments. The conductive layer 314 is made of W, Co, Al, Cu, or another suitable conductive material.

As shown in FIG. 1O, a dielectric layer 320 is formed over the dielectric layer 290 and the conductive line 310, in accordance with some embodiments. The dielectric layer 320 is made of an oxide-containing insulating material, such as silicon oxide, or a nitride-containing insulating material, such as silicon nitride, silicon oxynitride, silicon oxycarbonitride, or silicon carbonitride, in accordance with some embodiments.

The dielectric layer 320 is formed using a deposition process, in accordance with some embodiments. The deposition process includes an atomic layer deposition (ALD) process, a chemical vapor deposition (CVD) process, or another applicable process.

FIG. 1P-1 is a top view of the semiconductor device structure of FIG. 1P, in accordance with some embodiments. FIG. 1P is a cross-sectional view illustrating the semiconductor device structure along a sectional line I-I′ in FIG. 1P-1, in accordance with some embodiments. FIG. 1P-2 is a cross-sectional view illustrating the semiconductor device structure along a sectional line II-II′ in FIG. 1P-1, in accordance with some embodiments. FIG. 1P-3 is a cross-sectional view illustrating the semiconductor device structure along a sectional line III-III′ in FIG. 1P-1, in accordance with some embodiments.

As shown in FIGS. 1P and 1P-1, a portion of the dielectric layer 320 is removed to form a through hole 322 in the dielectric layer 320, in accordance with some embodiments. As shown in FIGS. 1P and 1P-1, a conductive via 330 is formed in the through hole 322 and over the conductive line 310, in accordance with some embodiments.

The conductive via 330 includes a barrier layer 332 and a conductive layer 334 over the barrier layer 332, in accordance with some embodiments. The barrier layer 332 is made of metal nitrides such as TaN or TiN, in accordance with some embodiments. The conductive layer 334 is made of W, Co, Al, Cu, or another suitable conductive material.

As shown in FIG. 1P-2, the inner spacer layer 160 electrically insulates the source/drain structures 170A from the n-type gate stack 270A, in accordance with some embodiments. As shown in FIG. 1P-3, the inner spacer layer 160 electrically insulates the source/drain structures 170B from the p-type gate stack 270B, in accordance with some embodiments.

FIG. 1Q-1 is a top view of the semiconductor device structure of FIG. 1Q, in accordance with some embodiments. FIG. 1Q is a cross-sectional view illustrating the semiconductor device structure along a sectional line I-I′ in FIG. 1Q-1, in accordance with some embodiments. FIG. 1Q-2 is a cross-sectional view illustrating the semiconductor device structure along a sectional line II-II′ in FIG. 1Q-1, in accordance with some embodiments. FIG. 1Q-3 is a cross-sectional view illustrating the semiconductor device structure along a sectional line III-III′ in FIG. 1Q-1, in accordance with some embodiments.

As shown in FIGS. 1Q-1, 1Q-2, and 1Q-3, portions of the dielectric layer 180, the etch stop layer 280, the dielectric layer 290, and the dielectric layer 320 are removed to form through holes TH2, TH3 and TH4, in accordance with some embodiments. The through holes TH2, TH3 and TH4 pass through the dielectric layer 180, the etch stop layer 280, the dielectric layer 290, and the dielectric layer 320, in accordance with some embodiments.

The through hole TH2 exposes the source/drain structures 170A and 170B, in accordance with some embodiments. The through hole TH3 exposes the source/drain structure 170A, in accordance with some embodiments. The through hole TH4 exposes the source/drain structure 170B, in accordance with some embodiments. The removal process includes an etching process, such as an anisotropic etching process (e.g., a dry etching process), in accordance with some embodiments.

As shown in FIGS. 1Q-1, 1Q-2, and 1Q-3, contact plugs 342, 344, and 346 are formed in the through holes TH2, TH3, and TH4 respectively, in accordance with some embodiments. The contact plugs 342, 344, and 346 are made of W, Co, Al, Cu, or another suitable conductive material.

In this step, a semiconductor device structure 300 is substantially formed, in accordance with some embodiments. The semiconductor device structure 300 is a complementary metal-oxide-semiconductor (CMOS) device, in accordance with some embodiments. The n-type gate stack 270A and the source/drain structures 170A together form an n-type transistor, in accordance with some embodiments. The p-type gate stack 270B and the source/drain structures 170B together form a p-type transistor, in accordance with some embodiments.

The isolation structure 210 separates the n-type gate stack 270A from the p-type gate stack 270B, which reduces process induced interferences between the work function metal layer 240 of the n-type gate stack 270A and the work function metal layer 250 of the p-type gate stack 270B, in accordance with some embodiments. Therefore, the formation of the isolation structure 210 improves the yield of the semiconductor device structure 300, in accordance with some embodiments.

Furthermore, since the interferences between the work function metal layer 240 of the n-type gate stack 270A and the work function metal layer 250 of the p-type gate stack 270B is reduced, the distance between the n-type gate stack 270A and the p-type gate stack 270B is able to be reduced, which improves an area scaling of the semiconductor device structure 300, in accordance with some embodiments.

As shown in FIG. 1Q, a width W120A of the nanostructure stack 120A or 120B ranges from about 8 nm to about 60 nm, in accordance with some embodiments. In some embodiments, a thickness T270A of the n-type gate stack 270A between the protective layer 190 and the nanostructure stack 120A ranges from about 10 nm to about 20 nm. In some embodiments, a thickness T190 of the protective layer 190 ranges from about 2 nm to about 6 nm. In some embodiments, a distance D11 between the fins 114 and 116 ranges from about 30 nm to about 60 nm.

In some embodiments, a width W310 of the conductive line 310 ranges from about 40 nm to about 80 nm. In some embodiments, a thickness T310 of the conductive line 310 ranges from about 15 nm to about 40 nm. In some embodiments, a width W330 of the conductive line 330 ranges from about 10 nm to about 20 nm. In some embodiments, a thickness T330 of the conductive line 330 ranges from about 15 nm to about 40 nm.

In some embodiments, a distance D between bottom surfaces BS1 and BS2 of two adjacent channel nanostructures 124B ranges from about 13 nm to about 20 nm. The distance D is also referred to as a pitch between two adjacent channel nanostructures 124B, in accordance with some embodiments. In some embodiments, two adjacent channel nanostructures 124A may have a distance substantially the same as the distance D.

FIGS. 2A-2F are cross-sectional views of various stages of a process for forming a semiconductor device structure, in accordance with some embodiments. After the step of FIG. 1A, as shown in FIG. 2A, a mask layer M1 is formed over the gate stack structure 140, in accordance with some embodiments.

The gate stack structure 140 includes a gate dielectric layer 142, a semiconductor layer 143, an etch stop layer 145, and a semiconductor layer 144, in accordance with some embodiments. The gate dielectric layer 142, the semiconductor layer 143, the etch stop layer 145, and the semiconductor layer 144 are sequentially stacked over the fins 114 and 116 and the nanostructure stacks 120A and 120B, in accordance with some embodiments.

In some embodiments, a thickness T143 of the semiconductor layer 143 ranges from about 5 nm to about 16 nm. The semiconductor layer 143 is made of a semiconductor material such as silicon, in accordance with some embodiments. The semiconductor layer 143 is formed using a deposition process such as an atomic layer deposition (ALD) process, a chemical vapor deposition (CVD) process, or another applicable process.

In some embodiments, a thickness T145 of the etch stop layer 145 ranges from about 1 nm to about 3 nm. The etch stop layer 145 is made of a metal oxide material such as Al₂O₃, in accordance with some embodiments. The etch stop layer 145 is formed using a deposition process such as an atomic layer deposition (ALD) process, a chemical vapor deposition (CVD) process, or another applicable process.

As shown in FIG. 2B, portions of the semiconductor layer 144 are removed to form trenches 144r passing through the semiconductor layer 144, in accordance with some embodiments. One of the trenches 144r is between the fins 114 and 116, in accordance with some embodiments. The semiconductor layer 144 is divided into semiconductor structures 144A and 144B, in accordance with some embodiments.

The semiconductor structure 144A has lower portions 144As, in accordance with some embodiments. The lower portions 144As cover the sidewalls 145s of the etch stop layer 145, in accordance with some embodiments. The semiconductor structure 144B has lower portions 144B s, in accordance with some embodiments. The lower portions 144Bs cover the sidewalls 145s of the etch stop layer 145, in accordance with some embodiments.

The trenches 144r in the semiconductor layer 144 expose lower portions 145a of the etch stop layer 145, in accordance with some embodiments. The removal process includes an etching process, such as an anisotropic etching process (e.g., a dry etching process), in accordance with some embodiments.

FIG. 2C-1 is a top view of the semiconductor device structure of FIG. 2C, in accordance with some embodiments. FIG. 2C is a cross-sectional view illustrating the semiconductor device structure along a sectional line I-I′ in FIG. 2C-1, in accordance with some embodiments.

As shown in FIGS. 2C and 2C-1, the semiconductor structures 144A and 144B are partially removed from the sidewalls 144s of the semiconductor structures 144A and 144B, in accordance with some embodiments. The removal process removes side portions and the lower portions 144As and 144Bs of the semiconductor structure 144A and 144B to widen the trenches 144r, in accordance with some embodiments.

Since the gate stack structure 140 includes the etch stop layer 145, the trenches 144r are self-aligned with the sidewalls 145s of the etch stop layer 145, in accordance with some embodiments. Therefore, the overlay accuracy requirement of the photolithography process for forming the mask layer M1 is reduced, in accordance with some embodiments. Therefore, the cost of the photolithography process is reduced, in accordance with some embodiments. Furthermore, the formation of the etch stop layer 145 improves the yield of the removal process for forming the trenches 144r, in accordance with some embodiments.

As shown in FIGS. 2C and 2C-1, portions of the etch stop layer 145, the semiconductor layer 143, and the gate dielectric layer 142 are removed through the trenches 144r to form trenches TR1, in accordance with some embodiments. The trenches TR1 pass through the etch stop layer 145, the semiconductor layer 143, and the gate dielectric layer 142, in accordance with some embodiments.

The gate stack structure 140 is divided into a gate stack 140A and a gate stack 140B by the trenches 144r and TR1, in accordance with some embodiments. In some embodiments, a width W144r of the trench 144r decreases toward the base 112. The width W144r ranges from about 10 nm to about 40 nm, in accordance with some embodiments.

The gate stack 140A has footing portions 140Af close to the isolation layer 130, in accordance with some embodiments. The footing portion 140Af protrudes toward the gate stack 140B, in accordance with some embodiments. The gate stack 140B has footing portions 140Bf close to the isolation layer 130, in accordance with some embodiments. The footing portion 140Bf protrudes toward the gate stack 140A, in accordance with some embodiments.

As shown in FIG. 2D, a protective layer 190 is conformally formed over the gate stacks 140A and 140B and the isolation layer 130, in accordance with some embodiments. As shown in FIG. 2D, an isolation structure 210 is formed over the protective layer 190, in accordance with some embodiments. The isolation structure 210 is in the trenches 144r, which pass through the semiconductor layer 144, and the trenches TR1, which pass through the etch stop layer 145, the semiconductor layer 143, and the gate dielectric layer 142, in accordance with some embodiments.

As shown in FIG. 2E, top portions of the protective layer 190 and the isolation structure 210, which are outside of the trenches 144r of the semiconductor layer 144 and the trenches TR1 are removed, in accordance with some embodiments. The removal process includes a planarization process such as a chemical mechanical polishing (CMP) process, in accordance with some embodiments.

FIG. 2F-1 is a top view of the semiconductor device structure of FIG. 2F, in accordance with some embodiments. FIG. 2F is a cross-sectional view illustrating the semiconductor device structure along a sectional line I-I′ in FIG. 2F-1, in accordance with some embodiments. FIG. 2F-2 is a cross-sectional view illustrating the semiconductor device structure along a sectional line II-II′ in FIG. 2F-1, in accordance with some embodiments. FIG. 2F-3 is a cross-sectional view illustrating the semiconductor device structure along a sectional line III-III′ in FIG. 2F-1, in accordance with some embodiments.

As shown in FIGS. 2F, 2F-1, 2F-2, and 2F-3, the steps of FIGS. 1F-1Q are performed to form the n-type gate stack 270A, the p-type gate stack 270B, the etch stop layer 280, the dielectric layer 290, the conductive line 310, the dielectric layer 320, and the conductive via 330, in accordance with some embodiments.

In this step, a semiconductor device structure 400 is substantially formed, in accordance with some embodiments. The semiconductor device structure 400 is a complementary metal-oxide-semiconductor (CMOS) device, in accordance with some embodiments.

The n-type gate stack 270A has footing portions 270Af, in accordance with some embodiments. The footing portions 270Af are close to the fin 114, in accordance with some embodiments. The footing portion 270Af protrudes toward the p-type gate stack 270B, in accordance with some embodiments. The p-type gate stack 270B has footing portions 270Bf, in accordance with some embodiments. The footing portions 270Bf are close to the fin 116, in accordance with some embodiments. The footing portion 270Bf protrudes toward the footing portion 270Af of the n-type gate stack 270A, in accordance with some embodiments.

The isolation structure 210 has an upper portion 212 and a lower portion 214, in accordance with some embodiments. The lower portion 214 is narrower than the upper portion 212, in accordance with some embodiments. That is, the width W214 of the lower portion 214 is less than the width W212 of the upper portion 212, in accordance with some embodiments.

Processes and materials for forming the semiconductor device structure 400 may be similar to, or the same as, those for forming the semiconductor device structure 300 described above. Elements designated by the same or similar reference numbers as those in FIGS. 1A to 2F-3 have the same or similar structures and the materials. Therefore, the detailed descriptions thereof will not be repeated herein.

In accordance with some embodiments, semiconductor device structures and methods for forming the same are provided. The methods (for forming the semiconductor device structure) form a trench in a poly gate stack structure to divide the poly gate stack structure into a first gate stack and a second gate stack before performing a metal gate replacement process. Thereafter, the metal gate replacement process is performed by removing the first gate stack and the second gate stack. The metal gate replacement process forms an n-type gate stack and a p-type gate stack. The n-type gate stack and the p-type gate stack are formed independently, which reduces process induced interferences between work function metal layers of the n-type gate stack and the p-type gate stack. Therefore, the yield of the semiconductor device structure is improved.

In accordance with some embodiments, a method for forming a semiconductor device structure is provided. The method includes providing a substrate, an isolation layer, a gate stack structure, and a dielectric layer. The substrate has a base, a first fin, and a second fin over the base, the isolation layer is over the base and surrounds the first fin and the second fin, the gate stack structure is wrapped around a first upper portion of the first fin and a second upper portion of the second fin, and the dielectric layer is over the isolation layer and wrapped around the gate stack structure. The method includes partially removing the gate stack structure to form a first trench in the gate stack structure. The gate stack structure is divided into a first gate stack and a second gate stack by the first trench, the first gate stack is over the first fin, and the second gate stack is over the second fin. The method includes forming an isolation structure in the first trench. The method includes removing the first gate stack and the second gate stack to form a first recess and a second recess in the dielectric layer. The method includes forming an n-type gate stack and a p-type gate stack in the first recess and the second recess respectively. The method includes forming a conductive line over the n-type gate stack, the p-type gate stack, and the isolation structure. The conductive line electrically connects the n-type gate stack to the p-type gate stack.

In accordance with some embodiments, a method for forming a semiconductor device structure is provided. The method includes providing a substrate, an isolation layer, and a gate stack structure. The substrate has a base, a first fin, and a second fin over the base, the isolation layer is over the base and surrounds the first fin and the second fin, the gate stack structure is wrapped around a first upper portion of the first fin and a second upper portion of the second fin, and the gate stack structure comprises a first semiconductor layer, an etch stop layer, a second semiconductor layer sequentially stacked over the substrate. The method includes partially removing the second semiconductor layer to form a first trench passing through the second semiconductor layer. The first trench is between the first fin and the second fin. The method includes partially removing the etch stop layer and the first semiconductor layer through the first trench to form a second trench passing through the etch stop layer and the first semiconductor layer. The gate stack structure is divided into a first gate stack and a second gate stack by the first trench and the second trench.

In accordance with some embodiments, a semiconductor device structure is provided. The semiconductor device structure includes a substrate having a base, a first fin, and a second fin over the base. The semiconductor device structure includes an n-type gate stack wrapped around a first upper portion of the first fin. The semiconductor device structure includes a p-type gate stack wrapped around a second upper portion of the second fin. The semiconductor device structure includes an isolation structure between the n-type gate stack and the p-type gate stack. The semiconductor device structure includes a conductive line over the n-type gate stack, the p-type gate stack, and the isolation structure. The conductive line electrically connects the n-type gate stack to the p-type gate stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
providing a substrate, an isolation layer, a gate stack structure, and a dielectric layer, wherein the substrate has a base, a first fin, and a second fin over the base, the isolation layer is over the base and surrounds the first fin and the second fin, the gate stack structure is wrapped around a first upper portion of the first fin and a second upper portion of the second fin, and the dielectric layer is over the isolation layer and wrapped around the gate stack structure;
partially removing the gate stack structure to form a first trench in the gate stack structure, wherein the gate stack structure is divided into a first gate stack and a second gate stack by the first trench, the first gate stack is over the first fin, and the second gate stack is over the second fin;
forming an isolation structure in the first trench;
removing the first gate stack and the second gate stack to form a first recess and a second recess in the dielectric layer;
forming an n-type gate stack and a p-type gate stack in the first recess and the second recess respectively; and
forming a conductive line over the n-type gate stack, the p-type gate stack, and the isolation structure, wherein the conductive line electrically connects the n-type gate stack to the p-type gate stack.

2. The method for forming the semiconductor device structure as claimed in claim 1, wherein the partially removing of the gate stack structure further forms a second trench and a third trench in the gate stack structure, the first gate stack is between the first trench and the second trench, and the second gate stack is between the first trench and the third trench.

3. The method for forming the semiconductor device structure as claimed in claim 2, wherein the isolation structure is further formed in the second trench and the third trench.

4. The method for forming the semiconductor device structure as claimed in claim 2, wherein a width of the first trench decreases toward the base.

5. The method for forming the semiconductor device structure as claimed in claim 1, further comprising:
forming a conductive via over the conductive line.

6. The method for forming the semiconductor device structure as claimed in claim 1, wherein the n-type gate stack comprises an n-type work function metal layer, and the p-type gate stack comprises a first p-type work function metal layer.

7. The method for forming the semiconductor device structure as claimed in claim 6, wherein the n-type gate stack further comprises a second p-type work function metal layer over the n-type work function metal layer.

8. The method for forming the semiconductor device structure as claimed in claim 7, wherein the first p-type work function metal layer and the second p-type work function metal layer are made of a same material.

9. The method for forming the semiconductor device structure as claimed in claim 1, further comprising:
providing a first nanostructure stack and a second nanostructure stack over the first fin and the second fin respectively, wherein the first nanostructure stack comprises a first nanostructure and a second nanostructure over the first nanostructure, the second nanostructure stack comprises a third nanostructure and a fourth nanostructure over the third nanostructure, the gate stack structure is wrapped around the first nanostructure stack and the second nanostructure stack; and
removing the first nanostructure and the third nanostructure after removing the first gate stack and the second gate stack, wherein the n-type gate stack is wrapped around the second nanostructure, and the p-type gate stack is wrapped around the fourth nano structure.

10. The method for forming the semiconductor device structure as claimed in claim 9, wherein the n-type gate stack is further wrapped around the first upper portion of the first fin, and the p-type gate stack is further wrapped around the second upper portion of the second fin.

11. A method for forming a semiconductor device structure, comprising:
providing a substrate, an isolation layer, and a gate stack structure, wherein the substrate has a base, a first fin, and a second fin over the base, the isolation layer is over the base and surrounds the first fin and the second fin, the gate stack structure is wrapped around a first upper portion of the first fin and a second upper portion of the second fin, and the gate stack structure comprises a first semiconductor layer, an etch stop layer, and a second semiconductor layer sequentially stacked over the substrate;
partially removing the second semiconductor layer to form a first trench passing through the second semiconductor layer, wherein the first trench is between the first fin and the second fin; and
partially removing the etch stop layer and the first semiconductor layer through the first trench to form a second trench passing through the etch stop layer and the first semiconductor layer, wherein the gate stack structure is divided into a first gate stack and a second gate stack by the first trench and the second trench.

12. The method for forming the semiconductor device structure as claimed in claim 11, further comprising:
providing a dielectric layer over the isolation layer and wrapped around the gate stack structure during providing the substrate, the isolation layer, and the gate stack structure;
after partially removing the etch stop layer and the first semiconductor layer through the first trench, forming an isolation structure in the first trench passing through the second semiconductor layer and the second trench passing through the etch stop layer and the first semiconductor layer;
removing the first gate stack and the second gate stack to form a first recess and a second recess in the dielectric layer; and
forming an n-type gate stack and a p-type gate stack in the first recess and the second recess respectively.

13. The method for forming the semiconductor device structure as claimed in claim 12, further comprising:
forming a conductive line over the n-type gate stack, the p-type gate stack, and the isolation structure, wherein the conductive line electrically connects the n-type gate stack to the p-type gate stack.

14. The method for forming the semiconductor device structure as claimed in claim 11, further comprising:
after partially removing the second semiconductor layer to form the first trench passing through the second semiconductor layer, removing a portion of the second semiconductor layer over a sidewall of the etch stop layer to widen the first trench.

15. The method for forming the semiconductor device structure as claimed in claim 11, wherein the first trench in the second semiconductor layer exposes a lower portion of the etch stop layer.

16. A semiconductor device structure, comprising:
a substrate having a base, a first fin, and a second fin over the base;
an n-type gate stack wrapped around a first upper portion of the first fin;
a p-type gate stack wrapped around a second upper portion of the second fin;
an isolation structure between the n-type gate stack and the p-type gate stack; and
a conductive line over the n-type gate stack, the p-type gate stack, and the isolation structure, wherein the conductive line electrically connects the n-type gate stack to the p-type gate stack.

17. The semiconductor device structure as claimed in claim 16, wherein the isolation structure separates the n-type gate stack from the p-type gate stack.

18. The semiconductor device structure as claimed in claim 16, wherein the n-type gate stack has a first footing portion close to the first fin and protruding toward the p-type gate stack.

19. The semiconductor device structure as claimed in claim 18, wherein the p-type gate stack has a second footing portion close to the second fin and protruding toward the first footing portion of the n-type gate stack.

20. The semiconductor device structure as claimed in claim 16, wherein the isolation structure has an upper portion and a lower portion, and the lower portion is narrower than the upper portion.
